(19) United States
(12) Patent Application Publication
(10) Pub. No.: US 2025/0007011 A1
(43) Pub. Date: Jan. 2, 2025

(54) Fast Reduced-Order Electrochemical Models For Lithium-Ion Batteries Under Various Charging And Discharging Rates

(71) Applicant: THE REGENTS OF THE UNIVERSITY OF MICHIGAN, ANN ARBOR, MI (US)

(72) Inventors: Wei Lu, ANN ARBOR, MI (US); Tianhan Gao, ANN ARBOR, MI (US)

(21) Appl. No.: 18/646,078

(22) Filed: Apr. 25, 2024

Related U.S. Application Data
(60) Provisional application No. 63/499,039, filed on Apr. 28, 2023.

(51) Int. Cl. H01M 10/42; H01M 10/0525; H01M 10/48

(52) U.S. Cl. CPC H01M 10/425; H01M 10/0525; H01M 10/484; H01M 10/486; H01M 2010/4271

(57) ABSTRACT

An electrical device can comprise: a battery including one or more electrochemical cells; a temperature sensor positioned in at least one of the electrochemical cells; a current sensor for measuring a current flowing from the battery; and a battery management system including a controller in electrical communication with the temperature sensor and the current sensor. The controller is configured to execute a program to: (i) calculate a terminal voltage of the battery using an electrochemical model that receives as inputs a temperature reading from the temperature sensor and the current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function, and (ii) determine a state of the battery based on the terminal voltage.

### CROSS-REFERENCES TO RELATED APPLICATIONS

This application is based on, claims benefit of, and claims priority to U.S. Application No. 63/499,039 filed on Apr. 28, 2023, which is hereby incorporated by reference herein in its entirety for all purposes.

### STATEMENT REGARDING FEDERALLY SPONSORED RESEARCH

Not Applicable.

### BACKGROUND OF THE INVENTION

### 1. Field of the Invention

This invention relates to methods for estimating a terminal voltage and/or a state of a battery and to an electrical device including a battery management system implementing one or more of the methods.

### 2. Description of the Related Art

Lithium-ion batteries have been one of the most popular choices for use as power sources in all-electric vehicles and hybrid electric vehicles. Their popularity is due to their high energy and power densities and their ability to achieve long driving ranges.

Knowing the amount of energy that is left in the battery gives the vehicle operator an idea of how long the vehicle can be used before recharging must take place. State of Charge (SOC) is an estimation used to compare the current state of the battery to the battery at full charge.

In all-electric vehicles, the SOC is used to determine the distance a vehicle can travel. When the SOC has fallen to a threshold, the driver of the vehicle must recharge the vehicle, much like refilling the fuel tank in a car. In hybrid electric vehicles, SOC determines when the engine is to be switched on and off. When SOC has fallen to a threshold, the engine is turned on to charge the battery and provide power to the vehicle.

As batteries age over time and use, the electrochemical processes within a battery change with every discharging and charging cycle and as the materials degrade. The state of health (SOH) of a battery is a measure (usually expressed as a percentage) that indicates the condition of a battery and its ability to deliver its specified performance compared to when it was new, i.e., at an SOH of 100%. Knowing the SOH of a battery is important for determining whether the battery may still be relied upon for a specific performance and if so, for how much longer.

Knowledge of the SOC and SOH is particularly important for lithium-ion batteries and therefore lithium-ion batteries are typically used in combination with an electronic battery management system that keeps the battery within a safe operating window by determining the internal state of the battery. Estimations of the states of a battery by a battery management system are mostly based on empirical equivalent circuit models. However, these models cannot reveal the internal chemical reactions of a battery. Consequently, physics-based electrochemical models, especially the pseudo-two-dimensional (P2D) model, have been widely studied due to their ability to capture the reaction kinetics of the battery electrodes. However, rigorous physical models involve high computational complexity due to their complex equations. As a result, pseudo-two-dimensional models require high-speed processors and therefore, it is difficult to use them in an actual battery management system.

What is needed therefore are methods for accelerating the calculations in physics-based electrochemical models such that the improved physics-based electrochemical models can be used in a battery management system or battery design optimization.

### SUMMARY OF THE INVENTION

The present invention addresses the foregoing needs by providing methods for estimating a terminal voltage and/or a state of a battery and to an electrical device including a battery management system implementing one or more of the methods.

In one aspect, the disclosure provides an electrical device including a battery management system implementing one or more of the methods of the present disclosure. The electrical device can comprise: a battery including one or more electrochemical cells; a temperature sensor positioned in at least one of the electrochemical cells; a current sensor for measuring a current flowing from the battery; and a battery management system including a controller in electrical communication with the temperature sensor and the current sensor. The controller is configured to execute a program stored in the controller to: (i) calculate a terminal voltage of the battery using an electrochemical model that receives as inputs a temperature reading from the temperature sensor and the current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function, and (ii) determine a state of the battery based on the terminal voltage.

In another aspect, the disclosure provides a method for estimating a terminal voltage of a battery including one or more electrochemical cells. The method comprises: (a) calculating a terminal voltage of the battery using an electrochemical model that receives as inputs a temperature reading from a temperature sensor positioned in at least one of the electrochemical cells and current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function.

In another aspect, the disclosure provides a method for estimating a state of a battery including one or more electrochemical cells. The method comprises: (a) calculating a terminal voltage of the battery using an electrochemical model that receives as inputs a temperature reading from a temperature sensor positioned in at least one of the electrochemical cells and current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function; and (b) determining a state of the battery based on the terminal voltage.

In another aspect, the disclosure provides a method in a data processing system comprising at least one processor and at least one memory, the at least one memory comprising instructions executed by the at least one processor to implement a terminal voltage estimation system for a battery including one or more electrochemical cells. The method comprises: (a) receiving as inputs a temperature from at least one of the electrochemical cells and a current flowing from the battery; and (b) calculating a terminal voltage of the battery using an electrochemical model that receives as inputs the temperature reading and the current and outputs the terminal voltage of the battery, wherein the electrochemical model calculates the terminal voltage of the battery using a lithium-ion concentration distribution as a first polynomial function and an electrolyte potential distribution as a second polynomial function.

In another aspect, the disclosure provides a method in a data processing system comprising at least one processor and at least one memory, at least one memory comprising instructions executed by the at least one processor to implement a state estimation system for a battery including one or more electrochemical cells. The method comprises: (a) receiving as inputs a temperature from at least one of the electrochemical cells and a current flowing from the battery; (b) calculating a terminal voltage of the battery using an electrochemical model that receives as inputs the temperature reading and the current and outputs the terminal voltage of the battery, wherein the electrochemical model calculates the terminal voltage of the battery using a lithium-ion concentration distribution as a first polynomial function and an electrolyte potential distribution as a second polynomial function; and (c) determining a state of the battery based on the terminal voltage.

Battery degradation is a time-varying and nonlinear electrochemical process. The internal physical mechanisms and failure modes are complicated. It is important for practical applications to accelerate the calculation while guaranteeing the accuracy for battery simulations. We developed novel reduced-order, physical-based electrochemical models, where the lithium-ion concentration and electrolyte potential distribution are represented in the space of polynomial functions. Two types of reduced-order models, revised single-particle model (RSPM) and fast-calculation P2D model (FCP2D), are developed. We developed an approach of using shape functions to construct weak form integration equations to determine unknown model parameters. The RSPM and FCP2D are coupled with various side-reaction mechanisms, such as solid electrolyte interphase (SEI) evolution, lithium plating, transition metal dissolution, hydrogen reduction, cathode film evolution, electrolyte oxidation, transition metal reduction, as well as the loss of active material (LAM). Results show that the RSPM and FCP2D can predict the battery states (such as terminal voltage, lithium-ion concentration, electrolyte potential) accurately (with an error below 2%) and efficiently. In particular, the RSPM is superfast (satisfactory accuracy with high efficiency) for calculating lower C-rate operations (e.g., under 2.5 C), while the FCP2D guarantees higher accuracy than the RSPM for calculating higher C-rate operations (e.g., above 2.5 C) while maintaining fast calculation. The selection of RSPM and FCP2D can be switched automatically based on the C rate to provide highly optimized calculation accuracy and efficiency. The RSPM and FCP2D can predict battery degradation accurately and efficiently. This method provides a novel approach to enhance physics-based battery simulation efficiency, which can be used for battery design optimization and for battery management system.

These and other features, aspects, and advantages of the present invention will become better understood upon consideration of the following detailed description, drawings, and appended claims.

### BRIEF DESCRIPTION OF THE DRAWINGS

FIG. 1 is a schematic of an electrical device including a lithium ion battery and a battery management system.

FIG. 1A is a schematic of a lithium-ion battery cell.

FIG. 2 shows in panel (a), the charging/discharging profiles for the dynamic driving simulations, and in panel (b), the equilibrium potential of NMC and graphite electrode materials.

FIG. 3 shows a comparison of terminal voltage calculated by the P2D model, RSPM, and FCP2D during charging in panel (a), and discharging in panel (b), under different C rates; the calculation error by the RSPM and FCP2D compared to a P2D model during charging in panel (c), and discharging in panel (d), under different C rates. The black dots and curves indicate 0.5 C, the red dots and curves indicate 1.0 C, the blue dots and curves indicate 2.0 C, the orange dots and curves indicate 3.0 C, the green dots and curves indicate 4.0 C, and the purple dots and curves indicate 5.0 C.

FIG. 4 shows a comparison of the lithium-ion concentration distribution along the electrode thickness or x-direction calculated by the P2D model, RSPM, and FCP2D during charging in panel (a), and discharging in panel (b), under different C rates when the average anode SOC reaches 0.5, when at the end of charging in panel (c), and when at the end of discharging in panel (d). The black dots and curves indicate 0.5 C, the red dots and curves indicate 1.0 C, the blue dots and curves indicate 2.0 C, the orange dots and curves indicate 3.0 C, the green dots and curves indicate 4.0 C, and the purple dots and curves indicate 5.0 C.

FIG. 5 shows a comparison of the electrolyte potential distribution along the electrode thickness direction calculated by the P2D model, RSPM, and FCP2D during charging in panel (a), and discharging in panel (b), under different C rates when the average anode SOC reaches 0.5, when at the end of charging in panel (c), and when at the end of discharging in panel (d). The black dots and curves indicate 0.5 C, the red dots and curves indicate 1.0 C, the blue dots and curves indicate 2.0 C, the orange dots and curves indicate 3.0 C, the green dots and curves indicate 4.0 C, and the purple dots and curves indicate 5.0 C.

FIG. 6 shows a comparison of the particle surface lithium concentration distribution along the electrode thickness direction calculated by the P2D model, RSPM, and FCP2D during charging in panel (a), and discharging in panel (b), under different C rates when the average anode SOC reaches 0.5; a comparison of interfacial current density distribution along the electrode thickness direction calculated by the P2D model, RSPM, and FCP2D during charging in panel (c), and discharging in panel (d), under different C rates when the average anode SOC reaches 0.5. The black dots and curves indicate 0.5 C, the red dots and curves indicate 1.0 C, the blue dots and curves indicate 2.0 C, the orange dots and curves indicate 3.0 C, the green dots and curves indicate 4.0 C, and the purple dots and curves indicate 5.0 C.

FIG. 7 shows a comparison of time consumption of the P2D model, RSPM, and FCP2D for simulating one complete constant current charging and discharging cycle under different C rates, wherein the graph bars for the P2D model, RSPM, and FCP2D are arranged left, middle, and right respectively for each of the different C rates as shown for the C rate of 3 in FIG. 7.

FIG. 8 shows a comparison of the terminal voltage curves generated by the RSPM and FCP2D compared to those by the P2D model for dynamic driving profile 1 in panel (a), dynamic driving profile 2 in panel (b), and dynamic driving profile 3 in panel (c); the voltage error by the RSPM and FCP2D for dynamic driving profile 1 in panel (d), dynamic driving profile 2 in panel (e), and dynamic driving profile 3 in panel (f).

### DETAILED DESCRIPTION OF THE INVENTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown and described, but are to be accorded the widest scope consistent with the principles and features disclosed herein. Skilled artisans will recognize the examples provided herein have many useful alternatives and fall within the scope of embodiments of the invention.

As used herein, the battery state of charge (SOC) gives the ratio of the amount of charges presently stored in the battery to the nominal rated capacity of the battery expressed as a percentage or a number in the range of 0 to 1. For example, for a battery with a 1 amp hours (Ah) capacity and having charges stored in the battery of 0.8 Ah, the SOC is 80% or 0.8. SOC can also be expressed as a unit, such as 0.8 Ah for a battery with a 1 Ah capacity and having charges stored in the battery of 0.8 Ah.

As used herein, the state of health (SOH) of a battery is a measure expressed as a percentage or a number in the range of 0 to 1 that indicates the condition of a battery and its ability to deliver its specified performance compared to when it was new, i.e., at an SOH of 100%.

As used herein, the term “C-rate” can be understood as follows. Charge and discharge rates of a battery are governed by C-rates. The capacity of a battery is commonly rated at 1C, meaning that a fully charged battery rated at 1 Ah should provide 1 amp (A) for one hour. The same battery discharging at 0.5C should provide 0.5 A for two hours, and at 2C, it delivers 2 A for 30 minutes. As illustrative examples, a C rate of 1C is also known as a one-hour charge or discharge; a C rate of 4C is a ¼-hour charge or discharge; a C rate of 2C is a ½-hour charge or discharge; a C rate of 0.5C or C/2 is a 2-hour charge or discharge; a C rate of 0.2C or C/5 is a 5-hour charge or discharge, and a C rate of 0.1C or C/10 is a 10-hour charge or discharge.

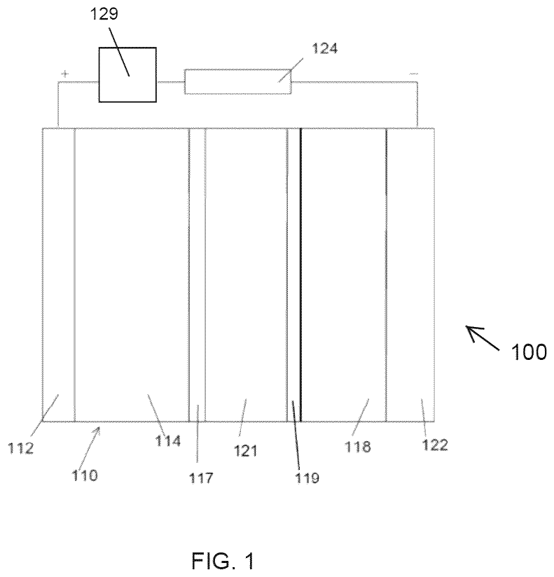

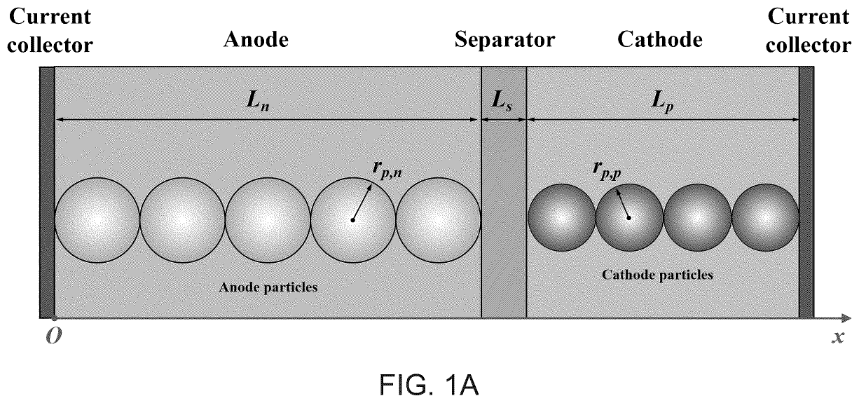

FIG. 1 shows a non-limiting example of an electrical device 100 including a lithium ion battery 110 and a battery management system 129 according to one embodiment of the present disclosure. The lithium ion battery 110 includes a first current collector 112 (e.g., aluminum) in contact with a cathode 114. A solid state electrolyte 121 is arranged between a solid electrolyte interphase 117 on the cathode 114 and a solid electrolyte interphase 119 on an anode 118, which is in contact with a second current collector 122 (e.g., copper). A solid electrolyte interphase may also be within a porous structure of the cathode 114, and a solid electrolyte interphase may also be within a porous structure of the anode 118. The first and second current collectors 112 and 122 of the lithium ion battery 110 may be in electrical communication with an electrical component 124. The electrical component 124 could place the lithium ion battery 110 in electrical communication with an electrical load that discharges the battery or a charger that charges the battery.

A suitable active material for the cathode 114 of the lithium ion battery 110 is a lithium host material capable of storing and subsequently releasing lithium ions. An example cathode active material is a lithium metal oxide wherein the metal is one or more aluminum, cobalt, iron, manganese, nickel and vanadium. Non-limiting example lithium metal oxides are LiCoO₂ (LCO), LiFeO₂, LiMnO₂ (LMO), LiMn₂O₄, LiNiO₂ (LNO), LiNixCoyO₂, LiMnxCoyO₂, LiMnₓNi_{y}O₂, LiMnₓNi_{y}O₄, LiNiₓCo_{y}Al_{z}O₂ (NCA), LiNi_{1/3}Mn_{1/3}Co_{1/3}O₂ and others. Another example of cathode active materials is a lithium-containing phosphate having a general formula LiMPO₄ wherein M is one or more of cobalt, iron, manganese, and nickel, such as lithium iron phosphate (LFP) and lithium iron fluorophosphates. The cathode can comprise a cathode active material having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The cathode active material can be a mixture of any number of these cathode active materials.

In some aspects, the cathode 114 may include a conductive additive. Many different conductive additives, e.g., Co, Mn, Ni, Cr, Al, or Li, may be substituted or additionally added into the structure to influence electronic conductivity, ordering of the layer, stability on delithiation and cycling performance of the cathode materials. Other suitable conductive additives include graphite, carbon black, acetylene black, Ketjen black, channel black, furnace black, lamp black, thermal black, conductive fibers, metallic powders, conductive whiskers, conductive metal oxides, and mixtures thereof.

A suitable active material for the anode 118 of the lithium ion battery 110 is a lithium host material capable of incorporating and subsequently releasing the lithium ion such as graphite (artificial, natural), a lithium metal oxide (e.g., lithium titanium oxide), hard carbon, a tin/cobalt alloy, silicon/carbon or lithium metal. The anode active material can be a mixture of any number of these anode active materials. In some embodiments, the anode 118 may also include one or more conductive additives similar to those listed above for the cathode 114.

A suitable solid state electrolyte 121 of the lithium ion battery 110 includes an electrolyte material having the formula LiᵤReᵥM_{w}AₓO_{y}, wherein
Re can be any combination of elements with a nominal valance of +3 including La, Nd, Pr, Pm, Sm, Sc, Eu, Gd, Tb, Dy, Y, Ho, Er, Tm, Yb, and Lu;
M can be any combination of metals with a nominal valance of +3, +4, +5 or +6 including Zr, Ta, Nb, Sb, W, Hf, Sn, Ti, V, Bi, Ge, and Si;
A can be any combination of dopant atoms with nominal valance of +1, +2, +3 or +4 including H, Na, K, Rb, Cs, Ba, Sr, Ca, Mg, Fe, Co, Ni, Cu, Zn, Ga, Al, B, and Mn;
u can vary from 3-7.5;
v can vary from 0-3;
w can vary from 0-2;
x can vary from 0-2; and
y can vary from 11-12.5.
   The electrolyte material may be an undoped or doped lithium lanthanum zirconium oxide.

Another example solid state electrolyte 121 can include any combination of oxide or phosphate materials with a garnet, perovskite, NaSICON, or LiSICON phase. The solid state electrolyte 121 of the lithium ion battery 110 can include any solid-like material capable of storing and transporting ions between the anode 118 and the cathode 114.

The current collector 112 and the current collector 122 can comprise a conductive material. For example, the current collector 112 and the current collector 122 may comprise molybdenum, aluminum, nickel, copper, combinations and alloys thereof or stainless steel.

Alternatively, a separator may replace the solid state electrolyte 121, and the electrolyte for the battery 110 may be a liquid electrolyte. An example separator material for the battery 110 can a permeable polymer such as a polyolefin. Example polyolefins include polyethylene, polypropylene, and combinations thereof. The liquid electrolyte may comprise a lithium compound in an organic solvent. The lithium compound may be selected from LiPF₆, LiBF₄, LiClO₄, lithium bis(fluorosulfonyl)imide (LiFSI), LiN(CF₃SO₂)₂(LiTFSI), and LiCF₃SO₃ (LiTf). The organic solvent may be selected from carbonate based solvents, ether based solvents, ionic liquids, and mixtures thereof. The carbonate based solvent may be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate; and the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane.

The solid electrolyte interphases 117, 119 form during a first charge of the lithium ion battery 110. To further describe the formation of a solid electrolyte interphase, a non-limiting example lithium ion battery 110 using a liquid electrolyte and having an anode comprising graphite is used in this paragraph. As lithiated carbons are not stable in air, the non-limiting example lithium ion battery 110 is assembled in its discharged state which means with a graphite anode and lithiated positive cathode materials. The electrolyte solution is thermodynamically unstable at low and very high potentials vs. Li/Li⁺. Therefore, on first charge of the lithium ion battery cell, the electrolyte solution begins to reduce/degrade on the graphite anode surface and forms the solid electrolyte interphase (SEI). There are competing and parallel solvent and salt reduction processes, which result in deposition of a number of organic and inorganic decomposition products on the surface of the graphite anode. The SEI layer imparts kinetic stability to the electrolyte against further reductions in the successive cycles and thereby ensures good cyclability of the electrode. It has been reported that SEI thickness may vary from few angstroms to tens or hundreds of angstroms. Studies suggest the SEI on a graphitic anode to be a dense layer of inorganic components close to the carbon of the anode, followed by a porous organic or polymeric layer close to the electrolyte phase.

The battery management system 129 may include an electronic controller to monitor various parameters associated with the operation of the lithium ion battery 110. For example, electrical signals from a temperature sensor, a pressure sensor, a current sensor, a voltage sensor, a capacity sensor, and so forth can be monitored by the controller of the battery management system. The controller may include memory storage which may store a program with one or more algorithms for the battery management system to use in order to calculate a terminal voltage of a battery or a state of the battery (e.g., state of charge or state of health) based on one or more of the sensed parameters.

The present invention is not limited to lithium ion batteries. In alternative embodiments, a suitable anode can comprise magnesium, sodium, or zinc. Suitable alternative cathode and electrolyte materials can be selected for such magnesium ion batteries, sodium ion batteries, or zinc ion batteries. For example, a sodium ion battery can include: (i) an anode comprising sodium ions, (ii) a solid state electrolyte comprising a metal cation-alumina (e.g., sodium-β-alumina or sodium-β″-alumina), and (iii) a cathode comprising an active material selected from the group consisting of layered metal oxides, (e.g., NaFeO, NaMnO, NaTiO, NaNiO, NaCrO, NaCoO, and NaVO) metal halides, polyanionic compounds, porous carbon, and sulfur containing materials.

In one embodiment of the invention, there is provided an electrical device including a battery management system implementing one or more of the methods of the present disclosure. The electrical device can comprise: a battery including one or more electrochemical cells; a temperature sensor positioned in at least one of the electrochemical cells; a current sensor for measuring a current flowing from the battery; and a battery management system including a controller in electrical communication with the temperature sensor and the current sensor. The controller is configured to execute a program stored in the controller to: (i) calculate a terminal voltage of the battery using an electrochemical model that receives as inputs a temperature reading from the temperature sensor and the current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function, and (ii) determine a state of the battery based on the terminal voltage. The electrochemical model can be a single-particle model. The electrochemical model can be a pseudo-two-dimensional electrochemical model. The electrochemical model can couple with a degradation mechanism. The degradation mechanism can be at least one of side-reactions, loss of active materials (LAM), and loss of lithium inventory (LLI). The state of the battery can be a state of charge percentage of the battery. The state of the battery can be a state of health percentage of the battery.

In the electrical device, the controller can be configured to execute the program stored in the controller to apply continuity conditions and boundary conditions to solve the first polynomial function and the second polynomial function. The controller can be configured to execute the program stored in the controller to solve the first polynomial function and the second polynomial function using a shape function. Parameters of the shape function can be obtained by optimization.

In the controller, step (i) can comprise calculating the terminal voltage of the battery using the electrochemical model that receives as inputs the temperature reading from the temperature sensor and the current flowing from the battery and outputs the terminal voltage of the battery when the battery is charged or discharged at a current below a C rate, and calculating the terminal voltage of the battery using an additional electrochemical model that receives as inputs the temperature reading from the temperature sensor and the current flowing from the battery and outputs the terminal voltage of the battery when the battery is charged or discharged at a current above the C rate, wherein the additional electrochemical model calculates the terminal voltage of the battery using a lithium-ion concentration distribution as a first polynomial function and an electrolyte potential distribution as a second polynomial function. In the electrical device, the electrochemical model can be a single-particle model, and the additional electrochemical model can be a pseudo-two-dimensional electrochemical model, and the electrochemical model can couple with a degradation mechanism. The degradation mechanism can be at least one of side-reactions, loss of active materials (LAM), and loss of lithium inventory (LLI). The C rate can be 2.5 C.

In the electrical device, the electrochemical model can calculate the terminal voltage of the battery using interfacial current density of the battery. The electrochemical model can calculate the terminal voltage of the battery using lithium concentration on surfaces of particles of the battery.

Each electrochemical cell can include an anode, an electrolyte, and a cathode including cations that move from the cathode to the anode during a charging phase of each electrochemical cell. The cations can be lithium cations. In one version of the electrical device, the anode can comprise an anode material selected from graphite, lithium titanium oxide, hard carbon, tin/cobalt alloys, silicon/carbon, or lithium metal, the electrolyte can comprise a liquid electrolyte including a lithium compound in an organic solvent, and the cathode can comprise a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). In one version of the electrical device, the anode can comprise graphite, the electrolyte can comprise a liquid electrolyte including a lithium compound in an organic solvent, the lithium compound can be selected from LiPF₆, LiBF₄, LiClO₄, lithium bis(fluorosulfonyl)imide (LiFSI), LiN(CF₃SO₂)₂(LiTFSI), and LiCF₃SO₃ (LiTf), the organic solvent can be selected from carbonate based solvents, ether based solvents, ionic liquids, and mixtures thereof, the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and the ether based solvent can be selected from the group consisting of diethyl ether, dibutyl ether, monoglyme, diglyme, tetraglyme, 2 methyltetrahydrofuran, tetrahydrofuran, 1,3-dioxolane, 1,2-dimethoxyethane, and 1,4-dioxane and mixtures thereof.

In another embodiment of the invention, there is provided a method for estimating a terminal voltage of a battery including one or more electrochemical cells. The method comprises: (a) calculating a terminal voltage of the battery using an electrochemical model that receives as inputs a temperature reading from a temperature sensor positioned in at least one of the electrochemical cells and current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function.

In another embodiment of the invention, there is provided a method for estimating a state of a battery including one or more electrochemical cells. The method comprises: (a) calculating a terminal voltage of the battery using an electrochemical model that receives as inputs a temperature reading from a temperature sensor positioned in at least one of the electrochemical cells and current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function; and (b) determining a state of the battery based on the terminal voltage.

In the method for estimating a terminal voltage of a battery and the method for estimating a state of a battery, the electrochemical model can be a single-particle model. The electrochemical model can be a pseudo-two-dimensional electrochemical model. The electrochemical model can couple with a degradation mechanism. The degradation mechanism can be at least one of side-reactions, loss of active materials (LAM), and loss of lithium inventory (LLI). The state of the battery can be a state of charge percentage of the battery. The state of the battery can be a state of health percentage of the battery. The controller can be configured to execute the program stored in the controller to apply continuity conditions and boundary conditions to solve the first polynomial function and the second polynomial function. The controller can be configured to execute the program stored in the controller to solve the first polynomial function and the second polynomial function using a shape function. Parameters of the shape function can be obtained by optimization.

In the method for estimating a terminal voltage of a battery and the method for estimating a state of a battery, step (a) can comprise calculating the terminal voltage of the battery using the electrochemical model that receives as inputs the temperature reading from the temperature sensor and the current flowing from the battery and outputs the terminal voltage of the battery when the battery is charged or discharged at a current below a C rate, and calculating the terminal voltage of the battery using an additional electrochemical model that receives as inputs the temperature reading from the temperature sensor and the current flowing from the battery and outputs the terminal voltage of the battery when the battery is charged or discharged at a current above the C rate, wherein the additional electrochemical model calculates the terminal voltage of the battery using a lithium-ion concentration distribution as a first polynomial function and an electrolyte potential distribution as a second polynomial function. The electrochemical model can be a single-particle model, and the additional electrochemical model can be a pseudo-two-dimensional electrochemical model, and the electrochemical model can couple with a degradation mechanism. The degradation mechanism can be at least one of side-reactions, loss of active materials (LAM), and loss of lithium inventory (LLI). The C rate can be 2.5 C. The electrochemical model can calculate the terminal voltage of the battery using interfacial current density of the battery. The electrochemical model can calculate the terminal voltage of the battery using lithium concentration on surfaces of particles of the battery.

In the method for estimating a terminal voltage of a battery and the method for estimating a state of a battery, each electrochemical cell can include an anode, an electrolyte, and a cathode including cations that move from the cathode to the anode during a charging phase of each electrochemical cell. The cations can be lithium cations. In one version of the methods, the anode can comprise an anode material selected from graphite, lithium titanium oxide, hard carbon, tin/cobalt alloys, silicon/carbon, or lithium metal, the electrolyte can comprise a liquid electrolyte including a lithium compound in an organic solvent, and the cathode can comprise a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). In one version of the methods, the anode can comprise graphite, the electrolyte can comprise a liquid electrolyte including a lithium compound in an organic solvent, the lithium compound is selected from LiPF₆, LiBF₄, LiClO₄, lithium bis(fluorosulfonyl)imide (LiFSI), LiN(CF₃SO₂)₂(LiTFSI), and LiCF₃SO₃ (LiTf), the organic solvent can be selected from carbonate based solvents, ether based solvents, ionic liquids, and mixtures thereof, the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and the ether based solvent can be selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

In another embodiment of the invention, there is provided a method in a data processing system comprising at least one processor and at least one memory, the at least one memory comprising instructions executed by the at least one processor to implement a terminal voltage estimation system for a battery including one or more electrochemical cells. The method comprises: (a) receiving as inputs a temperature from at least one of the electrochemical cells and a current flowing from the battery; and (b) calculating a terminal voltage of the battery using an electrochemical model that receives as inputs the temperature reading and the current and outputs the terminal voltage of the battery, wherein the electrochemical model calculates the terminal voltage of the battery using a lithium-ion concentration distribution as a first polynomial function and an electrolyte potential distribution as a second polynomial function.

In another embodiment of the invention, there is provided a method in a data processing system comprising at least one processor and at least one memory, at least one memory comprising instructions executed by the at least one processor to implement a state estimation system for a battery including one or more electrochemical cells. The method comprises: a) receiving as inputs a temperature from at least one of the electrochemical cells and a current flowing from the battery; (b) calculating a terminal voltage of the battery using an electrochemical model that receives as inputs the temperature reading and the current and outputs the terminal voltage of the battery, wherein the electrochemical model calculates the terminal voltage of the battery using a lithium-ion concentration distribution as a first polynomial function and an electrolyte potential distribution as a second polynomial function; and (c) determining a state of the battery based on the terminal voltage.

In the methods in a data processing system, the electrochemical model can be a single-particle model. The electrochemical model can be a pseudo-two-dimensional electrochemical model. The electrochemical model can couple with a degradation mechanism. The degradation mechanism can be at least one of side-reactions, loss of active materials (LAM), and loss of lithium inventory (LLI). The state of the battery can be a state of charge percentage of the battery. The state of the battery can be a state of health percentage of the battery. In the methods in a data processing system, step (b) can comprise applying continuity conditions and boundary conditions to solve the first polynomial function and the second polynomial function. Step (b) can comprise solving the first polynomial function and the second polynomial function using a shape function. Parameters of the shape function can be obtained by optimization.

In the methods in a data processing system, step (b) can comprise calculating the terminal voltage of the battery using the electrochemical model that receives as inputs the temperature and the current and outputs the terminal voltage of the battery when the battery is charged or discharged at a current below a C rate, and calculating the terminal voltage of the battery using an additional electrochemical model that receives as inputs the temperature and the current and outputs the terminal voltage of the battery when the battery is charged or discharged at a current above the C rate, wherein the additional electrochemical model calculates the terminal voltage of the battery using a lithium-ion concentration distribution as a first polynomial function and an electrolyte potential distribution as a second polynomial function. The electrochemical model can be a single-particle model, and the additional electrochemical model can be a pseudo-two-dimensional electrochemical model. The C rate can be 2.5 C.

In the methods in a data processing system, the electrochemical model can calculate the terminal voltage of the battery using interfacial current density of the battery. In the methods in a data processing system, the electrochemical model can calculate the terminal voltage of the battery using lithium concentration on surfaces of particles of the battery.

In the methods in a data processing system, each electrochemical cell can include an anode, an electrolyte, and a cathode including cations that move from the cathode to the anode during a charging phase of each electrochemical cell. The cations can be lithium cations. In the methods in a data processing system, the anode can comprise an anode material selected from graphite, lithium titanium oxide, hard carbon, tin/cobalt alloys, silicon/carbon, or lithium metal, the electrolyte can comprise a liquid electrolyte including a lithium compound in an organic solvent, and the cathode can comprise a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). In the methods in a data processing system, the anode can comprise graphite, the electrolyte can comprise a liquid electrolyte including a lithium compound in an organic solvent, the lithium compound can be selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf), the organic solvent can be selected from carbonate based solvents, ether based solvents, ionic liquids, and mixtures thereof, the carbonate based solvent can be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and the ether based solvent can be selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

### Example

The following Example has been presented in order to further illustrate the invention and is not intended to limit the invention in any way. The statements provided in the Example are presented without being bound by theory.

### Overview of Example

It is vital to accelerate the calculation efficiency while guaranteeing the accuracy for battery simulations. This Example introduces novel reduced-order, physical-based models using shape functions and basis of polynomial equations. Two types of reduced-order models, including the revised single-particle model (RSPM) and the fast-calculating P2D model (FCP2D), are developed. Specifically, we applied shape functions to construct weak form integration equations to solve the evolving parameters of polynomial equations, coupling all electrochemical and transport processes. Results show that the RSPM and FCP2D can predict various battery states, including terminal voltage, overpotential, interfacial current density, lithium-ion concentration distribution, and electrolyte potential distribution with high accuracy (error below 2%) and high efficiency (at least 3 times faster than the standard P2D model). The RSPM has a better performance (satisfactory accuracy with a higher efficiency) under lower C-rate operations (e.g., under 2.5 C), while the FCP2D guarantees a higher accuracy than the RSPM under higher C-rate operations (e.g., above 2.5 C). This Example provides a novel approach for improving battery simulation efficiency through physical-based models, which helps to accelerate the responding speed of battery management systems while improving accuracy, and accelerate battery design and optimization.

### 1. Introduction to Example

The battery cell in this Example is shown in FIG. 1A, which includes an anode (negative electrode), a separator, a cathode (positive electrode), and two current collectors. The thickness of the anode, separator, and cathode is Lₙ, Lₛ, and Lₚ, respectively. The material of the anode and cathode particles are selected to be graphite and NMC 811, respectively. The electrolyte is selected to be LiPF₆ in EC:DEC (1:1, v/v).

### 2. Methodology

### 2.1 Electrochemical and Transport Equations

The P2D model is widely used as a full electrochemical model for battery simulations. The solid and electrolyte potential are governed by

$$∇ \cdot ( {σ}_{s , i}^{eff} ∇ {ϕ}_{s , i} ) = {a}_{s , i} {i}_{loc , i} , \qquad ( 1 )$$

$$∇ \cdot ( - {κ}_{e , i}^{eff} ( ∇ {ϕ}_{e , i} - β ∇ ln {c}_{e , i} ) ) = {a}_{s , i} {i}_{loc , i} , \qquad ( 2 )$$

where i denotes a region in the battery cell (i=n for the negative electrode region, i=s for the separator region, and i=p for the positive electrode region). ϕ_{s,j} and ϕ_{e,i} denote the solid phase potential and the electrolyte phase potential, respectively. σ_{s,i}^{eff} and κ_{e,i}^{eff} denote the effective solid phase and electrolyte phase conductivity, respectively. They can be expressed by σ_{s,i}^{eff}=σ_{s0,i}ε_{s,i}^{burg} and κ_{e,i}^{eff}=κₑ₀ε_{e,i}^{burg} with σ_{s0,i} and κₑ₀ being the bulk solid phase and bulk electrolyte phase conductivity, ε_{i,j} and ε_{e,i} being the solid phase volume fraction and the electrolyte phase volume fraction, and burg being the Bruggeman constant. α_{s,i} denotes the active surface area per electrode volume, which can be expressed by α_{s,i}=3ε_{s,i}/r_{p,i} with r_{p,i} being the particle radius. i_{loc,i} denotes the interfacial current density. c_{e,i} denotes the lithium-ion concentration in the electrolyte phase. The parameter β is defined by

$$β = \frac{2 RT}{F} ( 1 + \frac{d ln {f}_{\pm }}{d ln {c}_{e , i}} ) ( 1 - {t}_{+}^{0} ) , \qquad ( 3 )$$

where R denotes ideal gas constant, T denotes temperature, F denotes Faraday's constant, and ƒ_{±} denotes the electrolyte activity coefficient. It is often assumed that dlnf_{±}ld lnc_{e,i}=0. t₊⁰ denotes the lithium-ion transference number. The lithium-ion concentration in electrolyte is governed by

$$\frac{\partial ( {ε}_{e , i} {c}_{e , i} )}{\partial t} = ∇ \cdot ( {D}_{e , i}^{eff} ∇ {c}_{e , i} ) + \frac{( 1 - {t}_{+}^{0} )}{F} {a}_{s , i} {i}_{loc , i} , \qquad ( 4 )$$

where t denotes time, and D_{e,i}^{eff} denotes the effective electrolyte diffusion coefficient given by D_{e,i}^{eff}=Dₑ₀ε_{e,i}^{burg} with Dₑ₀ being the lithium-ion diffusion coefficient in bulk electrolyte. The lithium concentration within each particle is governed by

$$\frac{\partial {c}_{s , i}}{\partial t} = \frac{1}{{r}^{2}} \frac{\partial }{\partial r} ( {D}_{s , i} {r}^{2} \frac{\partial {c}_{s , i}}{\partial r} ) , \qquad ( 5 )$$

where c_{i,j} denotes the lithium concentration in the particles, r denotes the radial coordinate, and D_{s,i} denotes the lithium diffusion coefficient of the solid phase. The interfacial current density, i_{loc, i}, is given by the Bulter-Volmer equation

$${i}_{loc , i} = {{Fk}_{i} ( {c}_{s , max , i} - {c}_{s , surf , i} )}^{α} {c}_{s , surf , i}^{1 - α} {c}_{e , i}^{α} [ exp ( \frac{α F {η}_{i}}{RT} ) - exp ( - \frac{( 1 - α ) F {η}_{i}}{RT} ) ] , \qquad ( 6 )$$

where κᵢ denotes the reaction rate constant, c_{s,max,i} denotes the maximum lithium ion concentration in the electrode particle, c_{s,surf,i} denotes the surface lithium ion concentration, a denotes the anodic charge transfer coefficient. The over-potential, ηᵢ, is given by ηᵢ=ϕ_{i,j}−ϕ_{e,i}−U_{eq,i} where U, denotes the equilibrium potential of anode or cathode.

The boundary conditions are

$$\frac{\partial {c}_{s , i}}{\partial r} {\vert}_{r = 0} = 0 , {D}_{s , i} \frac{\partial {c}_{s , i}}{\partial r} {\vert}_{r = {r}_{p , i}} = - \frac{{i}_{loc , i}}{F} . \qquad ( 7 )$$

$$\frac{\partial {c}_{e , n}}{\partial x} {\vert}_{x = 0} = 0 , \frac{\partial {c}_{e , p}}{\partial x} {\vert}_{x = {L}_{n} + {L}_{s} + {L}_{p}} = 0. \qquad ( 8 )$$

$$\frac{\partial {ϕ}_{e , n}}{\partial x} {\vert}_{x = 0} = 0 , \frac{\partial {ϕ}_{e , p}}{\partial x} {\vert}_{x = {L}_{n} + {L}_{s} + {L}_{p}} = 0 , {ϕ}_{e , n} {\vert}_{x = 0} = 0. \qquad ( 9 )$$

$${σ}_{s , p}^{eff} \frac{\partial {ϕ}_{s , p}}{\partial x} {\vert}_{x = {L}_{n} + {L}_{s} + {L}_{p}} = - {i}_{app} , \qquad ( 10 )$$

where iₐₚₚ denotes the applied current density (iₐₚₚ>0 for discharge). One can set any point in the battery as a reference point for 0 potential, and it is convenient to set ϕₑₙ|ₓ₌₀=0.

The continuity conditions for lithium-ion concentration, electrolyte potential, electrolyte current density i_{e,i}=−κ_{e,i}^{eff}(∇ϕ_{e,i}−β∇ ln c_{e,i}), and lithium ion flux N_{e,i}=−D_{e,i}^{eff}∇c_{e,i}+i_{e,i}t₊⁰/F are

$${c}_{e , n} {\vert}_{x = {L}_{n}} = {c}_{e , s} {\vert}_{x = {L}_{n}} , {c}_{e , s} {\vert}_{x = {L}_{n} + {L}_{s}} = {c}_{e , p} {\vert}_{x = {L}_{n} + {L}_{s}} , \qquad ( 11 )$$

$${ϕ}_{e , n} {\vert}_{x = {L}_{n}} = {ϕ}_{e , s} {\vert}_{x = {L}_{n}} , {ϕ}_{e , s} {\vert}_{x = {L}_{n} + {L}_{s}} = {ϕ}_{e , p} {\vert}_{x = {L}_{n} + {L}_{s}} . \qquad ( 12 )$$

$$- {κ}_{e , n}^{eff} ( \frac{\partial {ϕ}_{e , n}}{\partial x} - β \frac{\partial ln {c}_{e , n}}{\partial x} ) {\vert}_{x = {L}_{n}} = - {κ}_{e , s}^{eff} ( \frac{\partial {ϕ}_{e , s}}{\partial x} - β \frac{\partial ln {c}_{e , s}}{\partial x} ) {\vert}_{x = {L}_{n}} , \qquad ( 13 )$$

$$- {κ}_{e , s}^{eff} ( \frac{\partial {ϕ}_{e , s}}{\partial x} - β \frac{\partial ln {c}_{e , s}}{\partial x} ) {\vert}_{x = {L}_{n} + {L}_{s}} = - {κ}_{e , p}^{eff} ( \frac{\partial {ϕ}_{e , p}}{\partial x} - β \frac{\partial ln {c}_{e , p}}{\partial x} ) {\vert}_{x = {L}_{n} + {L}_{s}} . \qquad ( 14 )$$

$$- {D}_{e , n}^{eff} \frac{\partial {c}_{e , n}}{\partial x} {\vert}_{x = {L}_{n}} = - {D}_{e , s}^{eff} \frac{\partial {c}_{e , s}}{\partial x} {\vert}_{x = {L}_{n}} , \qquad ( 15 )$$

$$- {D}_{e , s}^{eff} \frac{\partial {c}_{e , s}}{\partial x} {\vert}_{x = {L}_{n} + {L}_{s}} = - {D}_{e , p}^{eff} \frac{\partial {c}_{e , p}}{\partial x} {\vert}_{x = {L}_{n} + {L}_{s}} . \qquad ( 16 )$$

The single-particle model (SPM) is widely used to simplify the electrochemical model to accelerate calculation. The SPM considers the two electrodes of a battery cell as two particles, and assumes that the lithium-ion concentration in the electrolyte and the electrolyte potential in each electrode are uniform. With this assumption, the terminal voltage can be solved analytically. A major limitation of the SPM is that the underlying assumptions are only valid under very low charging and discharging C-rates. The SPM gives poor prediction under higher C-rates, when the gradient of lithium-ion concentration and electrolyte potential are significant and cannot be neglected. Thus, appropriate reduced-order physics-based electrochemical models are required to accelerate the calculation while maintaining high accuracy under various C-rates.

### 2.2 Shape Functions and Integral Form to Solve Evolving Parameters

The types of reduced-order models in this Example include a revised single-particle model (RSPM) and a fast-calculating P2D model (FCP2D). In the RSPM, the interfacial current density is time-dependent but is assumed to be uniformly distributed at each moment within the anode and cathode. So when dealing with the current density, the anode and cathode can be represented by two particles. The RSPM considers spatial-dependent lithium-ion concentration in the electrolyte and spatial-dependent electrolyte potential, thus overcomes the limitation of the traditional single particle model and gives accurate results at higher C-rates. The FCP2D is even more accurate, where the interfacial current density is no longer assumed to be uniform but is calculated locally, which gives higher accuracy than the RSPM especially at very high C-rates. For both the RSPM and FCP2D, the lithium-ion concentration and the electrolyte potential distribution along the electrode thickness are represented by polynomials, c_{e,i}=α_{i,0}(t)+α_{i,1}(t)xᵢ+α_{i,2}(t)xᵢ²+α_{i,3}(t)xᵢ³ and ϕ_{e,i}=b_{i,0}(t)+b_{i,1}(t)xᵢ+b_{i,2}(t)xᵢ²+b_{i,3}(t)xᵢ³, where αᵢ(t) and bᵢ(t) are time-dependent polynomial parameters, and xi is the normalized position in region i along the electrode thickness

$${x}_{n} = \frac{x}{{L}_{n}} , {x}_{s} = \frac{x - {L}_{n}}{{L}_{s}} , {x}_{p} = \frac{x - {L}_{n} - {L}_{s}}{{L}_{p}} , \qquad ( 17 )$$

With these polynomials, the lithium-ion concentrations in the anode, separator, and cathode regions are

$${c}_{e , n} = {a}_{n , 0} + {a}_{n , 1} {x}_{n} + {a}_{n , 2} {x}_{n}^{2} + {a}_{n , 3} {x}_{n}^{3} \qquad ( 18 )$$

$${c}_{e , s} = {a}_{s , 0} + {a}_{s , 1} {x}_{s} + {a}_{s , 2} {x}_{s}^{2} .$$

$${c}_{e , p} = {a}_{p , 0} + {a}_{p , 1} {x}_{p} + {a}_{p , 2} {x}_{p}^{2} + {a}_{p , 3} {x}_{p}^{3}$$

The electrolyte potentials in the anode and cathode regions are

$${ϕ}_{e , n} = {b}_{n , 0} + {b}_{n , 1} {x}_{n} + {b}_{n , 2} {x}_{n}^{2} + {b}_{n , 3} {x}_{n}^{3} \qquad ( 19 )$$

$${ϕ}_{e , p} = {b}_{p , 0} + {b}_{p , 1} {x}_{p} + {b}_{p , 2} {x}_{p}^{2} + {b}_{p , 3} {x}_{p}^{3} .$$

With Eq. (17), the boundary and continuity conditions in Eqs. (8), (11), (15) and (16) become

$$\frac{\partial {c}_{e , n}}{\partial {x}_{n}} {\vert}_{{x}_{n} = 0} = 0 , \frac{\partial {c}_{e , p}}{\partial {x}_{p}} {\vert}_{{x}_{p} = 1} = 0. \qquad ( 20 )$$

$${c}_{e , n} {\vert}_{x = {L}_{n}} = {c}_{e , s} {\vert}_{x = {L}_{n}} , {c}_{e , s} {\vert}_{x = {L}_{n} + {L}_{s}} = {c}_{e , p} {\vert}_{x = {L}_{n} + {L}_{s}} , \qquad ( 21 )$$

$$- {D}_{e , n}^{eff} \frac{\partial {c}_{e , n}}{{L}_{n} \partial {x}_{n}} {\vert}_{{x}_{n} = 1} = - {D}_{e , s}^{eff} \frac{\partial {c}_{e , s}}{{L}_{s} \partial {x}_{s}} {\vert}_{{x}_{s} = 0} , \qquad ( 22 )$$

$$- {D}_{e , p}^{eff} \frac{\partial {c}_{e , p}}{{L}_{p} \partial {x}_{p}} {\vert}_{{x}_{p} = 0} = - {D}_{e , s}^{eff} \frac{\partial {c}_{e , s}}{{L}_{s} \partial {x}_{s}} {\vert}_{{x}_{s} = 1} . \qquad ( 23 )$$

Substituting Eq. (18) into the 6 constrains in Eqs. (21)-(23) reduces the number of unknown polynomial parameters for lithium-ion concentrations from 11 to 5. Choosing α_{n,0}, α_{n,2}, α_{n,3}, α_{s,2} and α_{p,3} as the independent parameters, we have

$${a}_{n , 1} = 0 , \qquad ( 24 )$$

$${a}_{s , 0} = {a}_{n , 0} + {a}_{n , 2} + {a}_{n , 3} , \qquad ( 25 )$$

$${a}_{s , 1} = 2 {R}_{1} {a}_{n , 2} + 3 {R}_{1} {a}_{n , 3} , \qquad ( 26 )$$

$${a}_{p , 0} = {a}_{n , 0} + ( 1 + 2 {R}_{1} ) {a}_{n , 2} + ( 1 + 3 {R}_{1} ) {a}_{n , 3} + {a}_{s , 2} , \qquad ( 27 )$$

$${a}_{p , 1} = 2 {R}_{1} {R}_{2} {a}_{n , 2} + 3 {R}_{1} {R}_{2} {a}_{n , 3} + 2 {R}_{2} {a}_{s , 2} , \qquad ( 28 )$$

$${a}_{p , 2} = - {R}_{1} {R}_{2} {a}_{n , 2} - \frac{3}{2} {R}_{1} {R}_{2} {a}_{n , 3} - {R}_{2} {a}_{s , 2} - \frac{3}{2} {a}_{p , 3} , \qquad ( 29 )$$

where

$${R}_{1} = \frac{{L}_{s}}{{L}_{n}} {( \frac{{ε}_{e , n}}{{ε}_{e , s}} )}^{burg} , {R}_{2} = \frac{{L}_{p}}{{L}_{s}} {( \frac{{ε}_{e , s}}{{ε}_{e , p}} )}^{burg} . \qquad ( 30 )$$

With Eq. (17), the boundary and continuity conditions in Eqs. (9) and (12)-(14) become

$$\frac{\partial {ϕ}_{e , n}}{\partial {x}_{n}} {\vert}_{{x}_{n} = 0} = 0 , \frac{\partial {ϕ}_{e , p}}{\partial {x}_{p}} {\vert}_{{x}_{p} = 1} = 0 , \qquad ( 31 )$$

$${ϕ}_{e , n} {\vert}_{{x}_{n} = 1} = {ϕ}_{e , s} {\vert}_{{x}_{s} = 0} , {ϕ}_{e , s} {\vert}_{{x}_{s} = 1} = {ϕ}_{e , p} {\vert}_{{x}_{p} = 0} , \qquad ( 32 )$$

$$- \frac{{κ}_{e , n}^{eff}}{{L}_{n}} ( \frac{\partial {ϕ}_{e , n}}{\partial {x}_{n}} - β \frac{\partial ln {c}_{e , n}}{\partial {x}_{n}} ) {\vert}_{{x}_{n} = 1} = - \frac{{κ}_{e , s}^{eff}}{{L}_{s}} ( \frac{\partial {ϕ}_{e , s}}{\partial {x}_{s}} - β \frac{\partial ln {c}_{e , s}}{\partial {x}_{s}} ) {\vert}_{{x}_{s} = 0} = {i}_{app} , \qquad ( 33 )$$

$$- \frac{{κ}_{e , s}^{eff}}{{L}_{s}} ( \frac{\partial {ϕ}_{e , s}}{\partial {x}_{s}} - β \frac{\partial ln {c}_{e , s}}{\partial {x}_{s}} ) {\vert}_{{x}_{s} = 1} = - \frac{{κ}_{e , p}^{eff}}{{L}_{p}} ( \frac{\partial {ϕ}_{e , p}}{\partial {x}_{p}} - β \frac{\partial ln {c}_{e , p}}{\partial {x}_{p}} ) {\vert}_{{x}_{p} = 0} = {i}_{app} . \qquad ( 34 )$$

Eqs. (33) and (34) can also be written as

$$- ( \frac{\partial {ϕ}_{e , n}}{\partial {x}_{n}} - β \frac{\partial ln {c}_{e , n}}{\partial {x}_{n}} ) {\vert}_{{x}_{n} = 1} = \frac{{L}_{n} {i}_{app}}{{κ}_{e , n}^{eff}} , \\ - ( \frac{\partial {ϕ}_{e , p}}{\partial {x}_{p}} - β \frac{\partial ln {c}_{e , p}}{\partial {x}_{p}} ) {\vert}_{{x}_{p} = 0} = \frac{{L}_{p} {i}_{app}}{{κ}_{e , p}^{eff}} \qquad ( 35 )$$

The electrolyte potential is defined relative to a reference, and it is convenient to choose the 0 potential by

$${ϕ}_{e , n} {\vert}_{{x}_{n} = 0} = 0. \qquad ( 36 )$$

Substituting Eq. (19) into the 5 constrains in Eqs. (31), (35) and (36) reduces the number of unknown polynomial parameters for electrolyte potentials from 8 to 3. Choosing b_{n,3}, b_{p,0} and b_{p,3} as the independent parameter, we have

$${b}_{n , 0} = 0 , \qquad ( 37 )$$

$${b}_{n , 1} = 0 , \qquad ( 38 )$$

$${b}_{n , 2} = \frac{β}{2} \frac{2 {a}_{n , 2} + 3 {a}_{n , 3}}{{a}_{n , 0} + {a}_{n , 2} + {a}_{n , 3}} - \frac{{L}_{n} {i}_{app}}{2 {κ}_{e , n}^{eff}} - \frac{3}{2} {b}_{n , 3} , \qquad ( 39 )$$

$${b}_{p , 1} = β \frac{{a}_{p , 1}}{{a}_{p , 0}} - \frac{{L}_{p} {i}_{app}}{{κ}_{e , p}^{eff}} , \qquad ( 40 )$$

$${b}_{p , 2} = - \frac{β}{2} \frac{{a}_{p , 1}}{{a}_{p , 0}} + \frac{{L}_{p} {i}_{app}}{2 {κ}_{e , p}^{eff}} - \frac{3}{2} {b}_{p , 3} . \qquad ( 41 )$$

The electrolyte potential in the separator region is solved by letting the right-hand side of Eq. (2) to be 0,

$$\frac{\partial }{\partial {x}_{s}} ( \frac{\partial {ϕ}_{e , s}}{\partial {x}_{s}} - β \frac{\partial ln {c}_{e , s}}{\partial {x}_{s}} ) = 0. \qquad ( 42 )$$

Integrating Eq. (42) and applying the conditions of Eqs. (32)-(34) gives

$${∅}_{e , s} = β ln ( {a}_{s , 0} + {a}_{s , 1} {x}_{s} + {a}_{s , 2} {x}_{s}^{2} ) - \frac{{L}_{s} {i}_{app}}{{κ}_{e , s}^{eff}} {x}_{s} + ( {b}_{n , 2} + {b}_{n , 1} - β ln ( {a}_{s , 0} ) ) , \qquad ( 43 )$$

and solves b_{p,0},

$${b}_{p , 0} = β ln ( \frac{{a}_{s , 0} + {a}_{s , 1} + {a}_{s , 2}}{{a}_{s , 0}} ) - ( \frac{{L}_{s}}{{κ}_{e , s}^{eff}} + \frac{{L}_{n}}{2 {κ}_{e , n}^{eff}} ) {i}_{app} + \frac{β}{2} \frac{2 {a}_{n , 2} + 3 {a}_{n , 2}}{{a}_{n , 0} + {a}_{n , 2} + {a}_{, 3}} - \frac{{b}_{n , 3}}{2} , \qquad ( 44 )$$

After the previous steps, we are left with 5 unknown polynomial parameters (α_{n,0}, α_{n,2}, α_{n,3}, α_{p,3}, α_{s,2}) for the lithium ion concentration and 2 unknown polynomial parameters (b_{n,3}, b_{p,3}) for the electrolyte potential. We proposal an innovative approach of using shape functions (kernel functions) to determine the unknown polynomial parameters. The key idea is to construct a weak integration form. To introduce the approach, consider solving an equation

$$f ( x ) = 0 . \qquad ( 45 )$$

An equivalent weak form (integration form) is constructed by using a shape function (kernel function), w(x), giving

$$\int w ( x ) \cdot f ( x ) = 0. \qquad ( 46 )$$

The shape function is given by

$$w ( x ) = {d}_{0} + {w}_{1} {x}_{i} + {w}_{2} {x}_{i}^{2} + {w}_{3} {x}_{i}^{3} , \qquad ( 47 )$$

where d₀ denotes the bias while w₁, w₂, w₃ denote three weights. Their values are pre-selected and known. In principle, any selected values are fine. We use optimization to determine a better choice of the bias and weight values.

We construct the following weak form for Eqs. (2) and (4)

$${\int }_{0}^{1} w ( x ) \frac{\partial {c}_{e , i}}{\partial t} d {x}_{i} = \frac{{D}_{e , i}^{eff}}{{ε}_{e , i} {L}_{i}^{2}} {\int }_{0}^{1} w ( x ) \frac{{\partial }^{2} {c}_{e , i}}{\partial {x}_{i}^{2}} {dx}_{i} + \frac{( 1 - {t}_{+}^{0} ) {a}_{s , i}}{{ε}_{e , i} F} {\int }_{0}^{1} w ( x ) {i}_{loc} d {x}_{i} , \qquad ( 48 )$$

$$- {\int }_{0}^{1} w ( x ) \frac{{\partial }^{2} {ϕ}_{e , i}}{\partial {x}_{i}^{2}} {dx}_{i} + β {\int }_{0}^{1} w ( x ) \frac{\partial }{\partial {x}_{i}} ( \frac{1}{{c}_{e , i}} \frac{\partial {c}_{e , i}}{\partial {x}_{i}} \} {dx}_{i} = \frac{{a}_{s , i} {L}_{i}^{2}}{{κ}_{e , i}^{eff}} {\int }_{0}^{1} w ( x ) {i}_{loc , i} d {x}_{i} , \qquad ( 49 )$$

We firstly set the bias d₀=1 and w₁=w₂=w₃=0 to construct 3 equations for solving the unknown polynomial parameters in lithium ion concentration, which give

$${\int }_{0}^{1} ( \frac{\partial {c}_{e , n}}{\partial t} ) {dx}_{n} = \frac{{D}_{e , n}^{eff}}{{ε}_{e , n} {L}_{n}^{2}} {\int }_{0}^{1} ( \frac{{\partial }^{2} {c}_{e , n}}{\partial {x}_{n}^{2}} ) {dx}_{n} + \frac{( 1 - {t}_{+}^{0} ) {a}_{s , n}}{{ε}_{e , n} F} {\int }_{0}^{1} {i}_{loc , n} {dx}_{n} , \qquad ( 50 )$$

$${\int }_{0}^{1} ( \frac{\partial {c}_{e , s}}{\partial t} ) {dx}_{s} = \frac{{D}_{e , s}^{eff}}{{ε}_{e , s} {L}_{s}^{2}} {\int }_{0}^{1} ( \frac{{\partial }^{2} {c}_{e , s}}{\partial {x}_{s}^{2}} ) {dx}_{s} , \qquad ( 51 )$$

$${\int }_{0}^{1} ( \frac{\partial {c}_{e , p}}{\partial t} {dx}_{p} = \frac{{D}_{e , p}^{eff}}{{ε}_{e , p} {L}_{p}^{2}} {\int }_{0}^{1} ( \frac{{\partial }^{2} {c}_{e , p}}{\partial {x}_{p}^{2}} ) {dx}_{p} + \frac{( 1 - {t}_{+}^{0} ) {a}_{s , p}}{{ε}_{e , p} F} {\int }_{0}^{1} {i}_{loc , p} {dx}_{p} . \qquad ( 52 )$$

The total reaction current in the anode and cathode relates to iₐₚₚ by

$${\int }_{0}^{1} {a}_{s , n} {i}_{loc , n} {dx}_{n} = \frac{{i}_{app}}{{L}_{n}} , {\int }_{0}^{1} {a}_{s , p} {i}_{loc , p} {dx}_{p} = - \frac{{i}_{app}}{{L}_{p}} . \qquad ( 53 )$$

Substituting the electrolyte concentration in Eq. (18), the relations in Eq. (24)-(29), and Eq. (53) into Eqs. (50)-(52), we get

$$\frac{{da}_{n , 0}}{dt} + \frac{1}{3} \frac{{da}_{n , 2}}{dt} + \frac{1}{4} \frac{{da}_{n , 3}}{dt} = {P}_{n} ( 2 {a}_{n , 2} + 3 {a}_{n , 3} ) + {Q}_{n} {i}_{app} , \qquad ( 54 )$$

$$\frac{{da}_{n , 0}}{dt} + ( 1 + {R}_{1} ) \frac{{da}_{n , 2}}{dt} + ( 1 + \frac{3}{2} {R}_{1} ) \frac{{da}_{n , 3}}{dt} + \frac{1}{3} \frac{{da}_{s , 2}}{dt} = 2 {P}_{s} {a}_{s , 2} , \qquad ( 55 )$$

$$\frac{{da}_{n , 0}}{dt} + ( 1 + 2 {R}_{1} + \frac{2}{3} {R}_{1} {R}_{2} ) \frac{{da}_{n , 2}}{dt} + ( 1 + 3 {R}_{1} + {R}_{1} {R}_{2} ) \frac{{da}_{n , 3}}{dt} + ( 1 + \frac{2}{3} {R}_{2} ) \text{} \frac{{da}_{s , 2}}{dt} - \text{} \frac{1}{4} \text{} \frac{{da}_{p , 3}}{dt} \cdot = \text{} - {P}_{p} ( \text{} 2 {R}_{1} {R}_{2} {a}_{n , 2} + 3 {R}_{1} {R}_{2} {a}_{n , 3} + 2 {R}_{2} {a}_{s 2 ,} ) - {Q}_{p} {I}_{app} \qquad ( 56 )$$

where

$${P}_{n} = \frac{{D}_{e , n}^{eff}}{{ε}_{e , n} {L}_{n}^{2}} , \qquad ( 57 )$$

$${P}_{s} = \frac{{D}_{e , s}^{eff}}{{ε}_{e , s} {L}_{s}^{2}} ,$$

$${P}_{p} = \frac{{D}_{e , p}^{eff}}{{ε}_{e , p} {L}_{p}^{2}} ,$$

$${Q}_{n} = \frac{( 1 - {t}_{+}^{0} )}{{ε}_{e , n} {FL}_{n}} ,$$

$${Q}_{p} = \frac{( 1 - {t}_{+}^{0} )}{{ε}_{e , p} {FL}_{p}} .$$

Eqs. (54)-(56) give 3 ordinary differential equations involving the 5 independent variables α_{n,0}, α_{n,2}, α_{n,3}, α_{s,2} and a_{p,3}. The weak form of Eq. (49) with d₀=1 and w₁=w₂=w₃=0 gives the same equations as Eq. (35), which have already been used. Next, we set the bias d₀=0 and use w₁, w₂, w₃ (at least one of them is non-zero) to construct 4 more equations. The expression of the local interfacial current density in the RSPM and FCP2D are different, leading to different ways to construct the remaining equations.

### 2.2.1 Revised Single-Particle Model (RSPM)

The RSPM assumes uniform interfacial current density, which allows obtaining an analytical form,

$${i}_{loc , n , RSPM} = \frac{{i}_{app}}{{a}_{s , n} {L}_{n}} , \qquad ( 58 )$$

$${i}_{loc , p , RSPM} = - \frac{{i}_{app}}{{a}_{s , p} {L}_{p}} .$$

Substituting the electrolyte concentration in Eq. (18), the relations in Eq. (24)-(29), w(x)=w₁xᵢ+w₂xᵢ²+w₃xᵢ³ and Eq. (58) into Eqs. (48), we get

$$( \frac{1}{2} {w}_{1} + \frac{1}{3} {w}_{2} + \frac{1}{4} {w}_{3} ) \frac{{da}_{n , 0}}{dt} + ( \frac{1}{4} {w}_{1} + \frac{1}{5} {w}_{2} + \text{} \frac{1}{6} {w}_{3} ) \text{} \frac{{da}_{n , 2}}{dt} + \text{} ( \frac{1}{5} {w}_{1} + \frac{1}{6} {w}_{2} + \text{} \frac{1}{7} {w}_{3} ) \text{} \frac{{da}_{n , 3}}{dt} \text{} = \text{} {w}_{1} \text{} {P}_{n} ( \text{} {a}_{n , 2} + \text{} 2 {a}_{n , 3} ) + {w}_{2} {P}_{n} ( \frac{2}{3} {a}_{n , 2} + \frac{3}{2} {a}_{n , 3} ) + {w}_{3} {P}_{n} ( \frac{1}{2} {a}_{n , 2} + \frac{6}{5} {a}_{n , 3} ) + ( \frac{1}{2} {w}_{1} + \frac{1}{3} {w}_{2} + \frac{1}{4} {w}_{3} ) {Q}_{n} {i}_{app} \qquad ( 59 )$$

$$and$$

$$( \frac{1}{2} {w}_{1} + \frac{1}{3} {w}_{2} + \frac{1}{4} {w}_{3} ) \frac{{da}_{n , 0}}{dt} + \text{} ( ( \frac{1}{2} + {R}_{1} + \frac{5}{12} {R}_{1} {R}_{2} ) {w}_{1} + ( \frac{1}{3} + \frac{2 {R}_{1}}{3} + \frac{3}{10} {R}_{1} {R}_{2} ) {w}_{2} + ( \frac{1}{4} + \frac{{R}_{1}}{2} + \frac{7}{30} {R}_{1} {R}_{2} ) {w}_{3} ) \frac{{da}_{n , 2}}{dt} + ( ( \frac{1}{2} + \frac{3 {R}_{1}}{2} + \frac{5}{8} {R}_{1} {R}_{2} ) {w}_{1} + ( \frac{1}{3} + {R}_{1} + \frac{9}{20} {R}_{1} {R}_{2} ) {w}_{2} + ( \frac{1}{4} + \frac{3 {R}_{1}}{4} + \frac{7}{20} {R}_{1} {R}_{2} ) {w}_{3} ) \frac{{da}_{n , 3}}{dt} + ( ( \frac{1}{2} + \frac{5}{12} {R}_{2} ) {w}_{1} + ( \frac{1}{3} + \frac{3}{10} {R}_{2} ) {w}_{2} + ( \frac{1}{4} + \frac{7}{30} {R}_{2} ) \text{} {w}_{3} ) \text{} \frac{{da}_{s , 2}}{dt} - ( \frac{7}{40} {w}_{1} + \frac{2}{15} {w}_{2} + \frac{3}{28} {w}_{3} ) \frac{{da}_{p , 3}}{dt} = \text{} - ( {w}_{1} + \frac{2}{3} {w}_{2} + \frac{1}{2} {w}_{3} ) {R}_{1} {R}_{2} {P}_{p} {a}_{n , 2} - ( \frac{3}{2} {w}_{1} + {w}_{2} + \frac{3}{4} {w}_{3} ) {R}_{1} {R}_{2} {P}_{p} {a}_{n , 3} - ( {w}_{1} + \frac{2}{3} {w}_{2} + \frac{1}{2} {w}_{3} ) \text{} {R}_{2} \text{} {P}_{p} \text{} {a}_{s 2} + \text{} ( \frac{1}{2} {w}_{1} + \frac{1}{2} {w}_{2} + \frac{9}{20} {w}_{3} ) \text{} {P}_{p} {a}_{p 3} - ( \frac{1}{2} {w}_{1} + \frac{1}{3} {w}_{2} + \frac{1}{4} {w}_{3} ) {Q}_{p} {i}_{app} \qquad ( 60 )$$

Next, we construct the 2 equations to solve b_{n,3} b_{p,3} for the electrolyte potential. Substituting the electrolyte potential in Eq. (19), w(x)=w₁xᵢ+w₂xᵢ²+w₃xᵢ³ and Eq. (58) into Eq. (49), we get

$$β {\int }_{0}^{1} ( {w}_{1} {x}_{n} + {w}_{2} {x}_{n}^{2} + {w}_{3} {x}_{n}^{3} ) \text{} ( \frac{\begin{matrix}( 2 {a}_{n , 2} + 6 {a}_{n , 3} {x}_{n} ) ( {a}_{n , 0} + {a}_{n , 1} {x}_{n} + {a}_{n , 2} {x}_{n}^{2} + \\ {a}_{n , 3} {x}_{n}^{3} ) - {( {a}_{n , 1} + 2 {a}_{n , 2} {x}_{n} + 3 {a}_{n , 3} {x}_{n}^{2} )}^{2}\end{matrix}}{{( {a}_{n , 0} + {a}_{n , 1} {x}_{n} + {a}_{n , 2} {x}_{n}^{2} + {a}_{n , 3} {x}_{n}^{3} )}^{2}} ) \text{} {dx}_{n} , = {w}_{1} ( {b}_{n , 2} + 2 {b}_{n , 3} ) + {w}_{2} ( \frac{2}{3} {b}_{n , 2} + \frac{3}{2} {b}_{n , 3} ) + {w}_{3} ( \frac{1}{2} {b}_{n , 2} + \frac{6}{5} {b}_{n , 3} ) + ( \frac{1}{2} {w}_{1} + \frac{1}{3} {w}_{2} + \frac{1}{4} {w}_{3} ) \frac{{L}_{n} {i}_{app}}{{κ}_{e , n}^{eff}} \qquad ( 61 )$$

$$β {\int }_{0}^{1} ( {w}_{1} {x}_{p} + {w}_{2} {x}_{p}^{2} + {w}_{3} {x}_{p}^{3} ) \text{} ( \frac{\begin{matrix}( 2 {a}_{p , 2} + 6 {a}_{p , 3} {x}_{p} ) ( {a}_{p , 0} + {a}_{p , 1} {x}_{p} + {a}_{p , 2} {x}_{p}^{2} + \\ {a}_{p , 3} {x}_{p}^{3} ) - {( {a}_{p , 1} + 2 {a}_{p , 2} {x}_{p} + 3 {a}_{p , 3} {x}_{p}^{2} )}^{2}\end{matrix}}{{( {a}_{p , 0} + {a}_{p , 1} {x}_{p} + {a}_{p , 2} {x}_{p}^{2} + {a}_{p , 3} {x}_{p}^{3} )}^{2}} ) \text{} {dx}_{p} . \text{} = {w}_{1} ( {b}_{p , 2} + 2 {b}_{p , 3} ) + {w}_{2} ( \frac{2}{3} {b}_{p , 2} + \frac{3}{2} {b}_{p , 3} ) + {w}_{3} ( \frac{1}{2} {b}_{p , 2} + \frac{6}{5} {b}_{p , 3} ) - ( \frac{1}{2} {w}_{1} + \frac{1}{3} {w}_{2} + \frac{1}{4} {w}_{3} ) \frac{{L}_{p} {i}_{app}}{{κ}_{e , p}^{eff}} \qquad ( 62 )$$

Substituting Eqs. (39) and (41) into the above two equations, we obtain the analytical expressions for b_{n,3} and b_{p,3},

$${b}_{n , 3} = \frac{20 β}{10 {w}_{1} + 10 {w}_{2} + 9 {w}_{3}} \times [ {\int }_{0}^{1} ( {w}_{1} {x}_{n} + {w}_{2} {x}_{n}^{2} + \text{} {w}_{3} {x}_{n}^{3} ) \text{} ( \frac{\begin{matrix}( 2 {a}_{n , 2} + 6 {a}_{n , 3} {x}_{n} ) ( {a}_{n , 0} + {a}_{n , 1} {x}_{n} + {a}_{n , 2} {x}_{n}^{2} + \\ {a}_{n , 3} {x}_{n}^{3} ) - {( {a}_{n , 1} + 2 {a}_{n , 2} {x}_{n} + 3 {a}_{n , 3} {x}_{n}^{2} )}^{2}\end{matrix}}{{( {a}_{n , 0} + {a}_{n , 1} {x}_{n} + {a}_{n , 2} {x}_{n}^{2} + {a}_{n , 3} {x}_{n}^{3} )}^{2}} ) \text{} {dx}_{n} - ( \text{} \frac{1}{2} {w}_{1} + \frac{1}{3} {w}_{2} + \frac{1}{4} {w}_{3} ) \frac{2 {a}_{n , 2} + 3 {a}_{n , 3}}{{a}_{n , 0} + {a}_{n , 2} + {a}_{n , 3}} ] \qquad ( 63 )$$

$${b}_{p , 3} = \frac{20 β}{10 {w}_{1} + 10 {w}_{2} + 9 {w}_{3}} \times [ {\int }_{0}^{1} ( {w}_{1} {x}_{p} + {w}_{2} {x}_{p}^{2} + {w}_{3} {x}_{p}^{3} ) \text{} ( \frac{\begin{matrix}( 2 {a}_{p , 2} + 6 {a}_{p , 3} {x}_{p} ) ( {a}_{p , 0} + {a}_{p , 1} {x}_{p} + {a}_{p , 2} {x}_{p}^{2} + \\ {a}_{p , 3} {x}_{p}^{3} ) - {( {a}_{p , 1} + 2 {a}_{p , 2} {x}_{p} + 3 {a}_{p , 3} {x}_{p}^{2} )}^{2}\end{matrix}}{{( {a}_{p , 0} + {a}_{p , 1} {x}_{p} + {a}_{p , 2} {x}_{p}^{2} + {a}_{p , 3} {x}_{p}^{3} )}^{2}} ) \text{} {dx}_{p} + ( \frac{1}{2} {w}_{1} + \frac{1}{3} {w}_{2} + \frac{1}{4} {w}_{3} ) \frac{{a}_{p , 1}}{{a}_{p , 0}} ] \qquad ( 64 )$$

To analytically solve the solid potential for the anode and cathode, we use the Bulter-Volmer equation

$${i}_{loc , i , RSPM} = {i}_{0 , i , RSPM} [ exp ( \frac{α F {η}_{i , RSPM}}{RT} ) - exp ( - \frac{( 1 - α ) F {η}_{i , RSPM}}{RT} ) ] , \qquad ( 65 )$$

where

$${i}_{0 , i , RSPM} = {{Fk}_{i} ( {c}_{s , max , i} - {c}_{s , surf , i} )}^{α} {( {c}_{s , surf , i} )}^{1 - α} {( {\overline{c}}_{e , i , ave} )}^{α} , \qquad ( 66 )$$

$${η}_{i , RSPM} = {ϕ}_{s , i} - {\overline{ϕ}}_{e , i , ave} - {U}_{eq , i} . \qquad ( 67 )$$

In the above expressions, c̅_{e,i,ave} denotes the average lithium-ion concentration along the thickness direction of the anode or cathode given by

$$\begin{matrix}{\overline{c}}_{e , n , ave} = \frac{1}{{L}_{n}} {\int }_{0}^{1} ( {a}_{n , 0} + {a}_{n , 1} {x}_{n} + {a}_{n , 2} {x}_{n}^{2} + {a}_{n , 3} {x}_{n}^{3} ) {dx}_{n} = \\ \frac{1}{{L}_{n}} ( {a}_{n , 0} + \frac{1}{2} {a}_{n , 1} + \frac{1}{3} {a}_{n , 2} + \frac{1}{4} {a}_{n , 3} ) \\ {\overline{c}}_{e , p , ave} = \frac{1}{{L}_{p}} {\int }_{0}^{1} ( {a}_{p , 0} + {a}_{p , 1} {x}_{p} + {a}_{p , 2} {x}_{p}^{2} + {a}_{p , 3} {x}_{p}^{3} ) {dx}_{p} = \\ \frac{1}{{L}_{p}} ( {a}_{p , 0} + \frac{1}{2} {a}_{p , 1} + \frac{1}{3} {a}_{p , 2} + \frac{1}{4} {a}_{p , 3} )\end{matrix} , \qquad ( 68 )$$

while ϕ̅_{e,i,ave} denotes the average electrolyte potential along the thickness direction of the anode or cathode given by

$$\begin{matrix}{\overline{ϕ}}_{e , n , ave} = \frac{1}{{L}_{n}} {\int }_{0}^{1} ( {b}_{n , 0} + {b}_{n , 1} {x}_{n} + {b}_{n , 2} {x}_{n}^{2} + {b}_{n , 3} {x}_{n}^{3} ) {dx}_{n} = \\ \frac{1}{{L}_{n}} ( {b}_{n , 0} + \frac{1}{2} {b}_{n , 1} + \frac{1}{3} {b}_{n , 2} + \frac{1}{4} {b}_{n , 3} ) \\ {\overline{ϕ}}_{e , p , ave} = \frac{1}{{L}_{p}} {\int }_{0}^{1} ( {b}_{p , 0} + {b}_{p , 1} {x}_{p} + {b}_{p , 2} {x}_{p}^{2} + {b}_{p , 3} {x}_{p}^{3} ) {dx}_{p} = \\ \frac{1}{{L}_{p}} ( {b}_{p , 0} + \frac{1}{2} {b}_{p , 1} + \frac{1}{3} {b}_{p , 2} + \frac{1}{4} {b}_{p , 3} )\end{matrix} , \qquad ( 69 )$$

We further define

$${m}_{n} = {i}_{app} / {Fk}_{n} {a}_{s , n} {{L}_{n} ( {c}_{s , max , n} - {c}_{s , surf , n} )}^{α} {( {c}_{s , surf , n} )}^{1 - α} {( {\overline{c}}_{e , n , ave} )}^{α} , \qquad ( 70 )$$

$${m}_{p} = - {i}_{app} / {Fk}_{p} {a}_{s , p} {{L}_{p} ( {c}_{s , max , p} - {c}_{s , surf , p} )}^{α} {( {c}_{s , surf , p} )}^{1 - α} {( {\overline{c}}_{e , p , ave} )}^{α} . \qquad ( 71 )$$

Take α=0.5 in this example, we solve the solid potential of the anode and cathode by

$${ϕ}_{s , n} = \qquad ( 72 )$$

$${η}_{n , RSPM} + {\overline{ϕ}}_{e , n , ave} + {U}_{eq , n} = \frac{2 RT}{F} ln ( \frac{\sqrt{{m}_{n}^{2} + 4} + {m}_{n}}{2} ) + {\overline{ϕ}}_{e , n , ave} + {U}_{eq , n} ,$$

$${ϕ}_{s , p} = \qquad ( 73 )$$

$${η}_{p , RSPM} + {\overline{ϕ}}_{e , p , ave} + {U}_{eq , p} = - \frac{2 RT}{F} ln ( \frac{\sqrt{{m}_{p}^{2} + 4} + {m}_{p}}{2} ) + {\overline{ϕ}}_{e , p , ave} + {U}_{eq , p} ,$$

The RSPM gives the terminal voltage of the battery cell as

$${V}_{t , RSPM} = {U}_{eq , p} - {U}_{eq , n} - \frac{2 RT}{F} ln ( \frac{\sqrt{{m}_{p}^{2} + 4} + {m}_{p}}{2} ) - \frac{2 RT}{F} ln ( \frac{\sqrt{{m}_{n}^{2} + 4} + {m}_{n}}{2} ) + {\overline{ϕ}}_{e , p , ave} - {\overline{ϕ}}_{e , n , ave} \qquad ( 74 )$$

### 2.2.2 Fast Calculation P2D Model (FCP2D)

The RSPM assumes the interfacial current density to be uniformly distributed along the thickness direction of the cathode or anode. The FCP2D remove this approximation to account for position-dependent interfacial current density.

Substituting the electrolyte concentration in Eq.(18), the relations in Eq.(24)-(29) and w(x)=w₁xᵢ+w₂xᵢ²+w₃xᵢ³ into Eq. (48), we get

$$( \frac{1}{2} {w}_{1} + \frac{1}{3} {w}_{2} + \frac{1}{4} {w}_{3} ) \frac{{da}_{n , 0}}{dt} + ( \frac{1}{4} {w}_{1} + \frac{1}{5} {w}_{2} + \frac{1}{6} {w}_{3} ) \frac{{da}_{n , 2}}{dt} + ( \frac{1}{5} {w}_{1} + \frac{1}{6} {w}_{2} + \frac{1}{7} {w}_{3} ) \frac{{da}_{n , 3}}{dt} = {w}_{1} {P}_{n} ( {a}_{n , 2} + 2 {a}_{n , 3} ) + {w}_{2} {P}_{n} ( \frac{2}{3} {a}_{n , 2} + \frac{3}{2} {a}_{n , 3} ) + {w}_{3} {P}_{n} ( \frac{1}{2} {a}_{n , 2} + \frac{6}{5} {a}_{n , 3} ) + {Q}_{n} {L}_{n} {a}_{s , n} {\int }_{0}^{1} ( {w}_{1} {x}_{n} + {w}_{2} {x}_{n}^{2} + {w}_{3} {x}_{n}^{3} ) {i}_{loc , n , FCP 2 D} {dx}_{n} , \qquad ( 75 )$$

$$and$$

$$( \frac{1}{2} {w}_{1} + \frac{1}{3} {w}_{2} + \frac{1}{4} {w}_{3} ) \frac{{da}_{n , 0}}{dt} + ( ( \frac{1}{2} + {R}_{1} + \frac{5}{12} {R}_{1} {R}_{2} ) {w}_{1} + ( \frac{1}{3} + \frac{2 {R}_{1}}{3} + \frac{3}{10} {R}_{1} {R}_{2} ) {w}_{2} + ( \frac{1}{4} + \frac{{R}_{1}}{2} + \frac{7}{30} {R}_{1} {R}_{2} ) {w}_{3} ) \frac{{da}_{n , 2}}{dt} + ( ( \frac{1}{2} + \frac{3 {R}_{1}}{2} + \frac{5}{8} {R}_{1} {R}_{2} ) {w}_{1} + ( \frac{1}{3} + {R}_{1} + \frac{9}{20} {R}_{1} {R}_{2} ) {w}_{2} + ( \frac{1}{4} + \frac{3 {R}_{1}}{4} + \frac{7}{20} {R}_{1} {R}_{2} ) {w}_{3} ) \frac{{da}_{n , 3}}{dt} + ( ( \frac{1}{2} + \frac{5}{12} {R}_{2} ) {w}_{1} + ( \frac{1}{3} + \frac{3}{10} {R}_{2} ) {w}_{2} + ( \frac{1}{4} + \frac{7}{30} {R}_{2} ) {w}_{3} ) \frac{{da}_{s , 2}}{dt} - ( \frac{7}{40} {w}_{1} + \frac{2}{15} {w}_{2} + \frac{3}{28} {w}_{3} ) \frac{{da}_{p , 3}}{dt} = - ( {w}_{1} + \frac{2}{3} {w}_{2} + \frac{1}{2} {w}_{3} ) {R}_{1} {R}_{2} {P}_{p} {a}_{n , 2} - ( \frac{3}{2} {w}_{1} + {w}_{2} + \frac{3}{4} {w}_{3} ) {R}_{1} {R}_{2} {P}_{p} {a}_{n , 3} - ( {w}_{1} + \frac{2}{3} {w}_{2} + \frac{1}{2} {w}_{3} ) {R}_{2} {P}_{p} {a}_{s , 2} + ( \frac{1}{2} {w}_{1} + \frac{1}{2} {w}_{2} + \frac{9}{20} {w}_{3} ) {P}_{p} {a}_{p , 3} + {Q}_{p} {L}_{p} {a}_{s , p} {\int }_{0}^{1} ( {w}_{1} {x}_{p} + {w}_{2} {x}_{p}^{2} + {w}_{3} {x}_{p}^{3} ) {i}_{loc , p , FCP 2 D} {dx}_{p} \qquad ( 76 )$$

where i_{loc,n,FCP2D} and the i_{loc,p,FCP2D} denote the interfacial current density in the anode and cathode, respectively. The 5 ordinary differential equations, Eqs. (54)-(56), (75) and (76), can be used to solve α_{n,0}, α_{n,2}, α_{n,3}, a_{s,2} and α_{p,3}.

Next, we construct the 2 equations to solve b_{n,3}, b_{p,3} for the electrolyte potential. Substituting the electrolyte potential in Eq. (19) and w(x)=w₁xᵢ+w₂xᵢ²+w₃xᵢ³ into Eq. (49), we get

$$β {\int }_{0}^{1} ( {w}_{1} {x}_{n} + {w}_{2} {x}_{n}^{2} + {w}_{3} {x}_{n}^{3} ) ( \frac{\begin{matrix}( 2 {a}_{n , 2} + 6 {a}_{n , 3} {x}_{n} ) \\ ( {a}_{n , 0} + {a}_{n , 1} {x}_{n} + {a}_{n , 2} {x}_{n}^{2} + {a}_{n , 3} {x}_{n}^{3} ) - \\ {( {a}_{n , 1} + 2 {a}_{n , 2} {x}_{n} + 3 {a}_{n , 3} {x}_{n}^{2} )}^{2}\end{matrix}}{{( {a}_{n , 0} + {a}_{n , 1} {x}_{n} + {a}_{n , 2} {x}_{n}^{2} + {a}_{n , 3} {x}_{n}^{3} )}^{2}} ) {dx}_{n} = {w}_{1} ( {b}_{n , 2} + 2 {b}_{n , 3} ) + {w}_{2} ( \frac{2}{3} {b}_{n , 2} + \frac{3}{2} {b}_{n , 3} ) + {w}_{3} ( \frac{1}{2} {b}_{n , 2} + \frac{6}{5} {b}_{n , 3} ) + \frac{{a}_{s , n} {L}_{n}^{2}}{{κ}_{e , n}^{eff}} \int ( {w}_{1} {x}_{n} + {w}_{2} {x}_{n}^{2} + {w}_{3} {x}_{n}^{3} ) {i}_{loc , n} {dx}_{n} , \qquad ( 77 )$$

$$β {\int }_{0}^{1} ( {w}_{1} {x}_{p} + {w}_{2} {x}_{p}^{2} + {w}_{3} {x}_{p}^{3} ) ( \frac{\begin{matrix}( 2 {a}_{p , 2} + 6 {a}_{p , 3} {x}_{p} ) \\ ( {a}_{p , 0} + {a}_{p , 1} {x}_{p} + {a}_{p , 2} {x}_{p}^{2} + {a}_{p , 3} {x}_{p}^{3} ) - \\ {( {a}_{p , 1} + 2 {a}_{p , 2} {x}_{p} + 3 {a}_{p , 3} {x}_{p}^{2} )}^{2}\end{matrix}}{{( {a}_{p , 0} + {a}_{p , 1} {x}_{p} + {a}_{p , 2} {x}_{p}^{2} + {a}_{p , 3} {x}_{p}^{3} )}^{2}} ) {dx}_{p} = {w}_{1} ( {b}_{p , 2} + 2 {b}_{p , 3} ) + {w}_{2} ( \frac{2}{3} {b}_{p , 2} + \frac{3}{2} {b}_{p , 3} ) + {w}_{3} ( \frac{1}{2} {b}_{p , 2} + \frac{6}{5} {b}_{p , 3} ) + \frac{{a}_{s , p} {L}_{p}^{2}}{{κ}_{e , p}^{eff}} \int ( {w}_{1} {x}_{p} + {w}_{2} {x}_{p}^{2} + {w}_{3} {x}_{p}^{3} ) {i}_{loc , p} {dx}_{p} , \qquad ( 78 )$$

Note that in the above four equations, the interfacial current density along the thickness direction is position-dependent and cannot be solved analytically. We first calculate mₙ and mₚ by Equations (70) and (71), and then obtain the solid potential distribution in the anode and cathode by

$${ϕ}_{s , n , FCP 2 D} ( {x}_{n} ) = \frac{2 RT}{F} ln ( \frac{\sqrt{{m}_{n}^{2} + 4} + {m}_{n}}{2} ) + {ϕ}_{e , n} + {U}_{eq , n} , \qquad ( 79 )$$

$${ϕ}_{s , p , FCP 2 D} ( {x}_{p} ) = - \frac{2 RT}{F} ln ( \frac{\sqrt{{m}_{p}^{2} + 4} + {m}_{p}}{2} ) + {ϕ}_{e , p} + {U}_{eq , p} , \qquad ( 80 )$$

Next, we calculate the position-dependent over-potential using ϕ_{s,n,FCP2D}(xₙ) and ϕ_{s,p,FCP2D}(xₚ) by

$${η}_{i , FCP 2 D} = {ϕ}_{s , i , RSPM} ( {x}_{i} ) - {ϕ}_{e , i} - {U}_{eq , i} , \qquad ( 81 )$$

The position-dependent local interfacial current density in the anode and cathode (i_{loc,n,FCP2D} and i_{loc,p,FCP2D}) is calculated by

$${i}_{loc , i , FCP 2 D} = {i}_{0 , i , FCP 2 D} [ exp ( \frac{α F {η}_{i , FCP 2 D}}{RT} ) - exp ( - \frac{( 1 - α ) F {η}_{i , FCP 2 D}}{RT} ) ] , \qquad ( 82 )$$

where

$${i}_{0 , i , FCP 2 D} = {{Fk}_{i} ( {c}_{s , max , i} - {c}_{s , surf , i} )}^{α} {( {c}_{s , surf , i} )}^{1 - α} {( {c}_{e , i} )}^{α} . \qquad ( 83 )$$

We substitute the i_{loc,n,FCP2D} and the i_{loc,p,FCP2D} calculated from the previous time step into Eqs (75)-(78) and solve them numerically for the next time step.

The FCP2D gives the terminal voltage of the battery cell as

$${V}_{t , FCP 2 D} = {ϕ}_{s , p , FCP 2 D} ( {x}_{p} = 1 ) - {ϕ}_{s , n , FCP 2 D} ( {x}_{n} = 0 ) . \qquad ( 84 )$$

### 2.3 Simulation Procedure and Performance Comparison

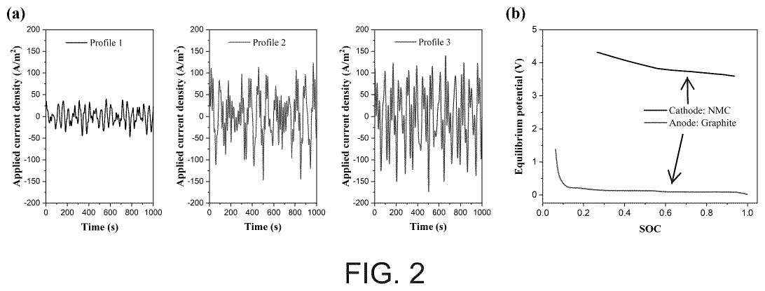

To demonstrate the performance of the RSPM and FCP2D, we introduce two charging/discharging modes in this Example. The first mode uses constant current to first charge and then discharge the battery. The C-rates of constant current charging and discharging include 0.5 C, 1.0 C, 2.0 C, 3.0 C, 4.0 C, and 5.0 C, respectively. For constant current charging, the cutoff voltage is set to be 4.2 V. For constant current discharging, the cutoff voltage is set to be 3.2 V. The second mode is to use random current density profiles to mimic the dynamic charging/discharging driving profiles during battery usage. Three random current density profiles are introduced in the second mode, as shown in FIG. 2 panels (a1-a3). The current density is produced by a combination of sine waves with different amplitude and angular frequency as shown by Eq. (A1) in the Appendix. The range of C rate of the dynamic driving profile 1, profile 2, and profile 3 is −1.4 to 1.2, −4.4 to 3.5, and −5.0 to 4.2, respectively. The simulation time span for each dynamic driving profile is 1000 seconds, and initial SOC (c_{s,suf,i}/c_{s,max,i}) of the cathode and anode is set to be 0.5. The equilibrium potential of the electrode materials are shown in FIG. 2 panel (b). The model parameters are listed in the Appendix below. The weights w₀, w₁, and w₂ in the shape function (Eq. (47)) in this Example are set to be 1.0, −3.0, −2.0, respectively for the RSPM, and 1.0, −1.6, −0.6, respectively for the FCP2D. These values are determined by optimization.

TABLE A1
Appendix: The Parameters Used in this Example
Values of electrochemical parameters used in simulations.

| Parameter | Symbol | Value | |
|---|---|---|---|
| Cₑ₀ | Initial lithium-ion concentration | 1000 | mol m⁻³ |
| C_{s, max, n} | Maximum lithium-ion concentration in the anode | 34347 | mol m⁻³ |
| | particle | | |
| C_{s, max, p} | Maximum lithium-ion concentration in the | 54789 | mol m⁻³ |
| | cathode particle | | |
| Dₑₒ | Lithium ion diffusion coefficient in bulk | 4 × 10⁻¹⁰ | m² s⁻¹ |
| | electrolyte | | |
| D_{s, n} | Lithium diffusion coefficient in the solid phase of | 2.93 × 10⁻¹⁴ | m² s⁻¹ |
| | anode | | |
| D_{s, p} | Lithium diffusion coefficient in the solid-phase of | 1.00 × 10⁻¹² | m² s⁻¹ |
| | cathode | | |
| F | Faraday constant | 96485° | C. mol⁻¹ |
| kₙ | Reaction rate constant of anode | 3.08 × 10⁻¹⁰ | m s⁻¹ |
| kₚ | Reaction rate constant of cathode | 1.30 × 10⁻¹⁰ | m s⁻¹ |
| Lₙ | Thickness of anode | 71.60 | μm |
| Lₚ | Thickness of cathode | 54.62 | μm |
| L | Thickness of separator | 9.00 | μm |
| r_{p, n} | Radius of the anode particle | 10.00 | μm |
| r_{p, p} | Radius of the cathode particle | 3.75 | μm |
| R | Ideal gas constant | 8.3145 | J mol⁻¹ K⁻¹ |
| t₊⁰ | Lithium-ion transference number | 0.363 | |
| α | Anodic charge transfer coefficient | 0.5 | |
| ε_{e, n} | Electrolyte volume fraction in anode | 0.315 | |
| ε_{e, p} | Electrolyte volume fraction in cathode | 0.265 | |
| ε_{e, s} | Electrolyte volume fraction in separator | 0.450 | |
| ε_{s, n} | Solid phase material volume fraction in anode | 0.585 | |
| ε_{s, p} | Solid phase material volume fraction in cathode | 0.635 | |
| κₑ₀ | Bulk electrolyte conductivity | 0.95 | S m⁻¹ |
| σ_{s0, n} | Bulk solid phase conductivity of anode | 50 | S m⁻¹ |
| σ_{s0, p} | Bulk solid phase conductivity of cathode | 13.75 | S m⁻¹ |

The formula for generating the dynamic driving profile is

$${i}_{app} = {A}_{1} sin ( {ω}_{1} t ) + {A}_{2} cos ( {ω}_{2} t ) + {A}_{3} sin ( {ω}_{3} t ) + {A}_{4} cos ( {ω}_{4} t ) + {A}_{5} sin ( {ω}_{5} t ) + {A}_{6} cos ( {ω}_{6} t ) . \qquad ( A1 )$$

The parameter values are shown in Table A2.

TABLE A2
Values of current density profile parameters

| Parameter | Profile 1 | Profile 2 | Profile 3 |
|---|---|---|---|
| A₁ | 0.600 | 1.200 | 2.000 |
| A₂ | 0.205 | 0.48 | 0.800 |
| A₃ | 0.125 | 0.336 | 0.560 |
| A₄ | 0.360 | 0.864 | 1.440 |
| A₅ | 0.070 | 1.368 | 0.280 |
| A₆ | 0.180 | 0.504 | 0.720 |
| ω₁ | 0.126 | 0.086 | 0.056 |
| ω₂ | 0.043 | 0.143 | 0.163 |
| ω₃ | 0.311 | 0.211 | 0.234 |
| ω₄ | 0.157 | 0.357 | 0.257 |
| ω₅ | 0.472 | 0.072 | 0.172 |
| ω₆ | 0.325 | 0.395 | 0.295 |

### 3. Results

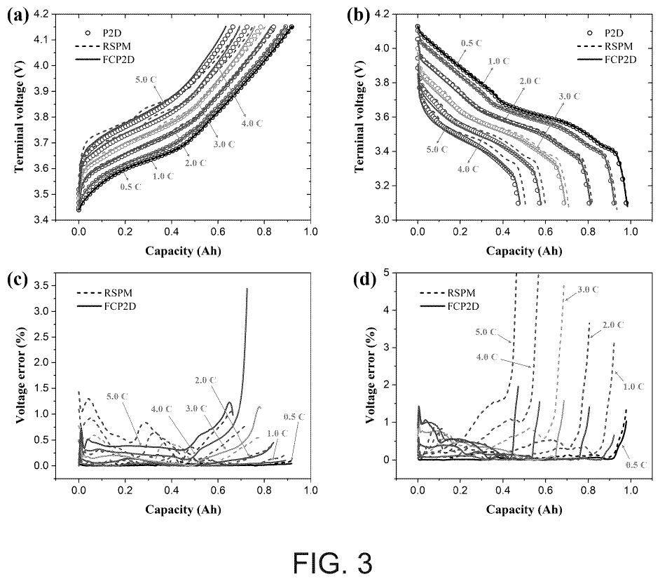

The performance of RSPM and FCP2D is presented here. The results generated by the standard P2D model are used as the benchmark for comparison. For the constant current charging/discharging mode, the terminal voltage curves of the battery cell calculated by the RSPM, FCP2D and P2D model are presented in FIG. 3 panels (a) and (b). Under lower C-rates (e.g., below 2.5 C), the terminal voltage curves by the RSPM and FCP2D both match well those by the P2D model. The error of the calculated terminal voltage during charging is almost all below 1% compared to the benchmark (as shown in FIG. 3 panel (c)). During discharging, the terminal voltage calculated by FCP2D and RSPM can maintain an error below 1% at most moments (as shown in FIG. 3 panel (d)). When the C-rate is high (e.g., above 2.5 C), the FCP2D can still maintain a high accuracy in calculating the terminal voltage, such that the error during charging is still maintained below 2% at most moments, and the error during discharging is still maintaining 2%. By contrast, the terminal voltage calculated by RSPM has less accuracy when the C-rate is high. For most moments, the error of the calculated terminal voltage by RSPM is larger than that by FCP2D. The error of RSPM at the end of discharging may exceed 5% at very high C-rates (shown in FIG. 3 panel (d)). The FCP2D is still accurate in calculating the battery terminal voltage under high C-rates, since the error is below 2% at most moments during charging and discharging.

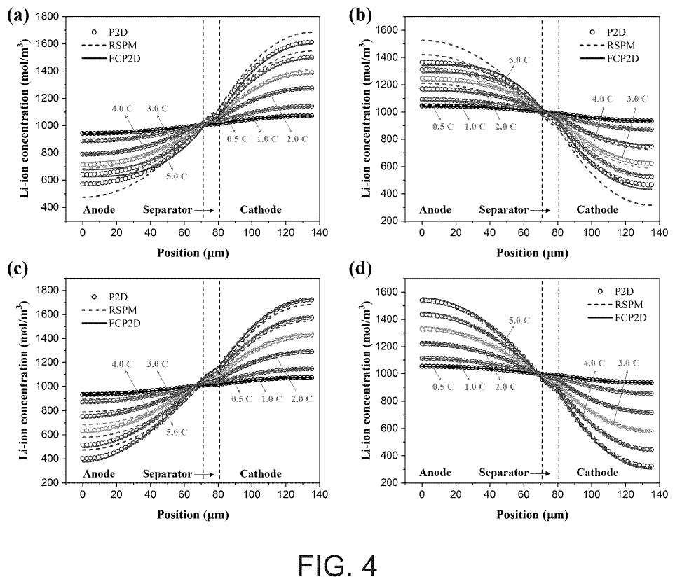

The lithium-ion concentration (cₑ) distribution curves calculated by the RSPM, FCP2D and P2D model are presented in FIG. 4. As the average anode SOC reaches 0.5, FIG. 4 panel (a) and panel (b) show that the cₑ distribution generated by the RSPM and FCP2D both match well those by the P2D model under low C rates. Under higher C rates, the cₑ distribution curves by the FCP2D can still match well those by the P2D model, while the cₑ distribution curves by the RSPM have a relatively larger error, especially near the current collector of the cathode and anode. At the end of charging and discharging, FIG. 4 panel (c) and panel (d) show that the cₑ distribution curves by FCP2D match well those by the P2D model under all the C-rate scenarios. The cₑ distribution curves by the RSPM also match well those by the P2D model under low C rates at the end of charging, while the cₑ curves by RSPM have a relatively large error under high C rates, especially near the current collector of the anode. By contrast, the cₑ distribution curves by FCP2D match well those by the P2D model under all the C-rate scenarios at the end of discharging (FIG. 4 panel (d)). These results indicate that the FCP2D can effectively capture the characteristics of lithium-ion concentration with high accuracy at the end of charging and discharging. The RSPM has relatively high accuracy in capturing the lithium-ion concentration at the end of charging and discharging, especially under low C rates. While in the middle of charging or discharging, the FCP2D still captures the lithium concentration with high accuracy, while the RSPM has relatively high accuracy under low C rates but limited accuracy under high C rates.

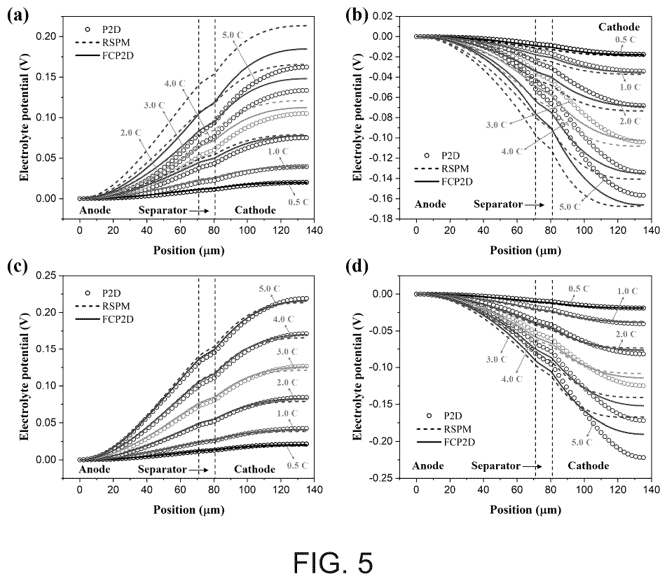

The electrolyte potential distribution curves calculated by the RSPM and FCP2D are presented in FIG. 5. As the average anode SOC reaches 0.5, FIG. 5 panel (a) and panel (b) show that the electrolyte potential distribution curves calculated by the RSPM and FCP2D both match well those by the P2D model under low C rates. Under high C rates, the electrolyte potential distribution by the FCP2D matches those by the P2D model with relatively high accuracy, while the electrolyte potential curves by the RSPM have a relatively large deviation. At the end of charging, FIG. 5 panel (c) shows that the electrolyte potential distribution curves by the RSPM and FCP2D both match well those by the P2D model with high accuracy. At the end of discharging, FIG. 5 panel (d) shows that the electrolyte potential distribution by the RSPM and FCP2D are accurate at most locations of the battery cell, while the RSPM has a has a higher error than the FCP2D at locations near the current collector of the cathode. These results indicate that during charging and discharging, the FCP2D has higher accuracy in capturing the electrolyte potential distribution that the RSPM. At the end of charging and discharging, the RSPM and FCP2D both capture the electrolyte potential accurately at most locations in the battery cell.

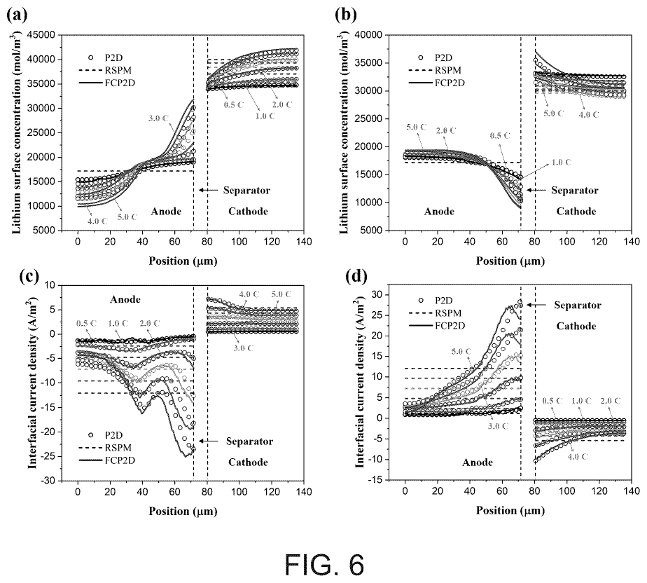

To further evaluate the performance of RSPM and FCP2D and understand the underlying mechanisms that cause their performances difference, the distribution of lithium concentration on the particle surface (c_{s,surf}) and the interfacial current density (i_{loc}) distribution are distilled and presented in FIG. 6. FIG. 6 panel (a) and panel (b) show that in the middle of charging and discharging, the c_{s,surf} distribution curves calculated by the FCP2D match well those by the P2D model under all C-rate scenarios. The FCP2D is able to capture the distribution of various electrochemical parameters accurately under all the C-rate scenarios because it describes the locally changing i_{loc} distribution along the battery thickness with high accuracy (see FIG. 6 panel (c) and panel (d)). This leads to high accuracy in predicting the terminal voltage.

The c_{s,surf} generated by RSPM is uniform for each electrode along the battery thickness, because the RSPM simplifies iₒc to be uniform in each electrode. Thus, the RSPM has limited accuracy under high C-rates (e.g., above 2.5 C), under which the polarization of i_{loc} distribution along the electrode thickness can be severe (see FIG. 6 panel (c) and panel (d)). Thus, the terminal voltage by RSPM under high C-rates is less accurate than that by FCP2D. The RSPM can capture the distribution of electrochemical parameters with high accuracy under low C-rates (e.g., under 2.5 C) since the polarization of i_{loc} distribution along the electrode thickness is less severe than that under high C-rates. Under low C-rates, the i_{loc} generated by the RSPM is almost the same as the average i_{loc} by the P2D model in each electrode. Thus, the terminal voltage calculated by RSPM under low C-rates has high accuracy.

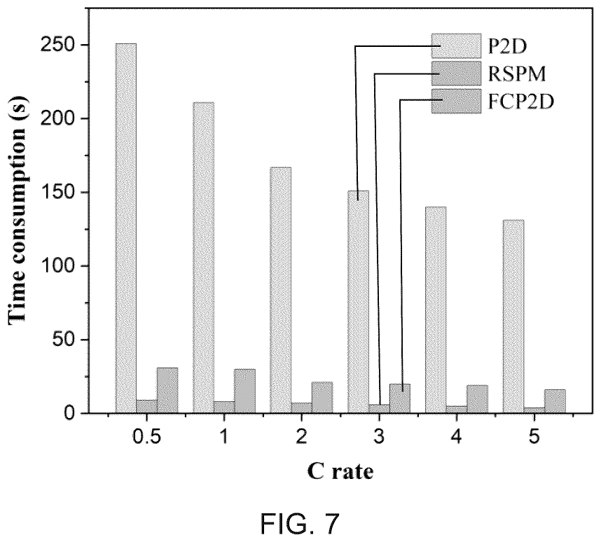

The time consumption of each model in completing one full charging and discharging cycle is compared in FIG. 7. The time consumption decreases monotonically with the C rate. The RSPM is the fastest, followed by the FCP2D. The P2D model is the slowest. The time consumption of RSPM is only 12.35%, 13.27%, 16.17%, 21.34%, 9.93%, and 9.22% of that of the P2D model under 0.5C, 1.0C, 2.0C, 3.0C, 4.0C, and 5.0C, respectively. The time consumption of FCP2D is 59.36%, 48.34%, 40.12%, 67.41%, 38.41%, and 37.59% of that of the P2D model. These results indicate that the RSPM has a higher efficiency than the FCP2D. However, when the C rate is high (e.g., above 2.5 C), the FCP2D offers better accuracy. A trade-off exists between accuracy and efficiency when selecting between the two models.

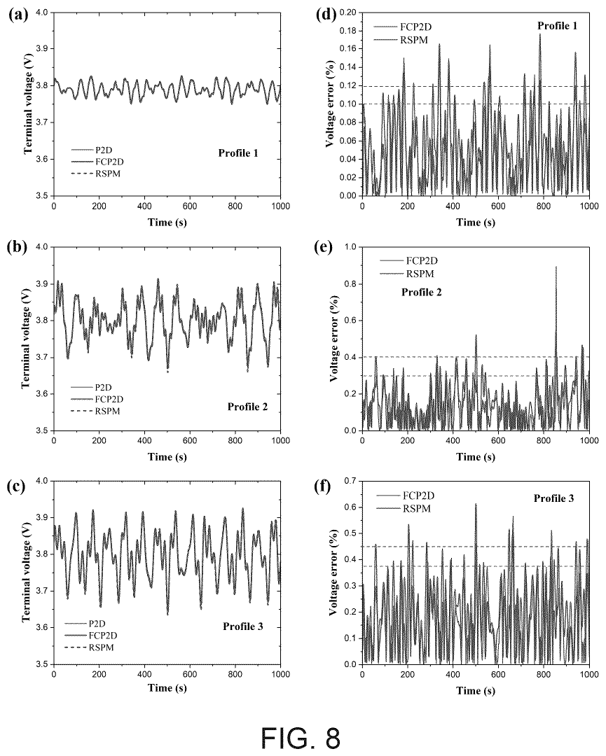

The accuracy of RSPM and FCP2D are further explored under the dynamic driving profiles based on the random charging/discharging profiles in FIG. 2 panel (a). The terminal voltage curves are presented in FIG. 8. FIG. 8 panels (a-c) show that for all three dynamic driving profiles, the terminal voltage curves by the RSPM and FCP2D match well those by the P2D model. The average voltage error of RSPM is 0.054%, 0.148%, and 0.190% in the dynamic driving profile 1, profile 2, and profile 3, respectively in the 1000 seconds time span. The average voltage error of FCP2D is 0.049%, 0.130%, and 0.174%, respectively in the 1000 seconds time span. For dynamic driving profile 1, FIG. 8 panel (d) shows that the transient voltage error of RSPM is mostly below 0.120% (indicated by the blue dash line), with a few moments when the error reaches around 0.160%, and the maximum error up to 0.180%. For the FCP2D, the transient voltage error is mostly below 0.100% (indicated by the red dash line), with a few moments when the error reaches around 0.14%, and the maximum error up to 0.168%. For dynamic driving profile 2, FIG. 8 panel (e) shows that the transient voltage error of RSPM is mostly below 0.400% (indicated by the blue dash line), with only one moment when the error reaches 0.900%. For the FCP2D, the transient voltage error is mostly below 0.300% (indicated by the red dash line), with a few moments when the error reaches around 0.350%, and the maximum error up to 0.460%. These are significantly lower than those of the RSPM. For dynamic driving profile 3, FIG. 8 panel (f) shows that the transient voltage error of RSPM is mostly below 0.450% (indicated by the blue dash line), with a few moments when the error reaches around 0.500%, and the maximum error up to 0.600%. For the FCP2D, the transient voltage error is mostly below 0.375% (as indicated by the red dash line), with a few moments when the error reaches around 0.400%, and the maximum error up to 0.570%.

The results show that RSPM and FCP2D both have high accuracy in simulating the battery terminal voltage under dynamic driving scenarios. The FCP2D has a higher overall accuracy (lower average voltage error) than the RSPM.

### 4. Conclusions

This Example demonstrates two novel reduced-order electrochemical models, revised single-particle-model (RSPM) and fast calculation P2D model (FCP2D), to accelerate battery simulation while maintaining high accuracy under various charging/discharging profiles. We modeled the electrolyte potential distribution and lithium-ion concentration distribution along the battery thickness direction as polynomials. We developed the shape function approach, together with the continuity and boundary conditions, to solve the unknown polynomial parameters. The shape function parameters were obtained by optimization.

Results show that both the RSPM and FCP2D can predict well the battery terminal voltage and electrochemical states, including lithium-ion concentration distribution, electrolyte potential distribution, interfacial current density, and lithium concentration on the particle surface with high accuracy and efficiency. Both the RSPM and FCP2D are much faster than the P2D model. The FCP2D has a higher accuracy than the RSPM, while the RSPM is faster. Both the RSPM and FCP2D predict the battery terminal voltage accurately under random charging/discharging conditions.

The predicted terminal voltage and optionally one or more of the electrochemical parameters can be used in a program stored in a controller of a battery management system to determine a state of a battery cell based on the terminal voltage calculated using the RSPM or FCP2D.

In one non-limiting example, the predicted terminal voltage and optionally one or more of the electrochemical parameters can be used in a program stored in a controller of a battery management system to determine a state of charge percentage of a battery cell based on the terminal voltage calculated using the RSPM or the FCP2D. Various algorithms for estimating state of charge are known in the art. See, for example, U.S. Pat. No. 10,074,996, which is incorporated herein by reference.

In another non-limiting example, the predicted terminal voltage and optionally one or more of the electrochemical parameters can be used in a program stored in a controller of a battery management system to determine a state of health percentage of a battery cell based on the terminal voltage calculated using the RSPM or the FCP2D. Various algorithms for estimating state of health are known in the art. See, for example, U.S. Pat. No. 10,393,813, which is incorporated herein by reference.

Thus, the invention provides methods for estimating a terminal voltage and/or a state of a battery and to an electrical device including a battery management system implementing one or more of the methods.

### REFERENCES

[1] T. Gao, W. Lu, “Machine learning toward advanced energy storage devices and systems”, IScience. 24 (2021) 101936. doi:10.1016/j.isci.2020.101936.
[2] T. Gao, W. Lu, “Physical Model and Machine Learning Enabled Electrolyte Channel Design for Fast Charging”, J. Electrochem. Soc. 167 (2020) 110519. doi:10.1149/1945-7111/aba096.
[3] D. Zhang, B. N. Popov, R. E. White, “Modeling lithium intercalation of a single spinel particle under potentiodynamic control”, J. Electrochem. Soc. 147 (2000) 831.
[4] L. Ren, G. Zhu, J. Kang, J. V. Wang, B. Luo, C. Chen, K. Xiang, “An algorithm for state of charge estimation based on a single-particle model”, J. Energy Storage. 39 (2021) 102644. doi:10.1016/j.est.2021.102644.
[5] S. K. Rechkemmer, X. Zang, W. Zhang, O. Sawodny, “Empirical Li-ion aging model derived from single particle model”, J. Energy Storage. 21 (2019) 773-786. doi:10.1016/j.est.2019.01.005.
[6] D. Zhang, S. Dey, S. J. Moura, “Lithium-Ion Battery State Estimation for a Single Particle Model with Intercalation-Induced Stress”, Proc. Am. Control Conf. 2018-June (2018) 2294-2299. doi:10.23919/ACC.2018.8431476.
[7] A. Aitio, S. G. Marquis, P. Ascencio, D. Howey, “Bayesian parameter estimation applied to the Li-ion battery single particle model with electrolyte dynamics”, IFAC—PapersOnLine. 53 (2020) 12497-12504. doi:10.1016/j.ifacol.2020.12.1770.
[8] A. M. Bizeray, J. H. Kim, S. R. Duncan, D. A. Howey, “Identifiability and Parameter Estimation of the Single Particle Lithium-Ion Battery Model”, IEEE Trans. Control Syst. Technol. 27 (2019) 1862-1877. doi:10.1109/TCST.2018.2838097.
[9] A. Pozzi, G. Ciaramella, S. Volkwein, D. M. Raimondo, “Optimal Design of Experiments for a Lithium-Ion Cell: Parameters Identification of an Isothermal Single Particle Model with Electrolyte Dynamics”, Ind. Eng. Chem. Res. 58 (2019) 1286-1299. doi:10.1021/acs.iecr.8b04580.
[10] H. Pang, L. Mou, L. Guo, F. Zhang, “Parameter identification and systematic validation of an enhanced single-particle model with aging degradation physics for Li-ion batteries”, Electrochim. Acta. 307 (2019) 474-487. doi:10.1016/j.electacta.2019.03.199.
   The citation of any document is not to be construed as an admission that it is prior art with respect to the present invention.

In light of the principles and example embodiments described and illustrated herein, it will be recognized that the example embodiments can be modified in arrangement and detail without departing from such principles. Also, the foregoing discussion has focused on particular embodiments, but other configurations are also contemplated. In particular, even though expressions such as “in one embodiment”, “in another embodiment,” or the like are used herein, these phrases are meant to generally reference embodiment possibilities, and are not intended to limit the invention to particular embodiment configurations. As used herein, these terms may reference the same or different embodiments that are combinable into other embodiments. As a rule, any embodiment referenced herein is freely combinable with any one or more of the other embodiments referenced herein, and any number of features of different embodiments are combinable with one another, unless indicated otherwise.

Although the invention has been described in considerable detail with reference to certain embodiments, one skilled in the art will appreciate that the present invention can be practiced by other than the described embodiments, which have been presented for purposes of illustration and not of limitation. Therefore, the scope of the appended claims should not be limited to the description of the embodiments contained herein.

1. An electrical device comprising:
a battery including one or more electrochemical cells;
a temperature sensor positioned in at least one of the electrochemical cells;
a current sensor for measuring a current flowing from the battery; and
a battery management system including a controller in electrical communication with the temperature sensor and the current sensor, the controller being configured to execute a program stored in the controller to:
(i) calculate a terminal voltage of the battery using an electrochemical model that receives as inputs a temperature reading from the temperature sensor and the current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function, and
(ii) determine a state of the battery based on the terminal voltage.

2. The electrical device of claim 1 wherein:
the electrochemical model is a single-particle model.

3. The electrical device of claim 1 wherein:
the electrochemical model is a pseudo-two-dimensional electrochemical model.

4. The electrical device of claim 1 wherein:
the electrochemical model can couple with a degradation mechanism.

5. The electrical device of claim 4 wherein:
the degradation mechanism is at least one of side-reactions, loss of active materials (LAM), and loss of lithium inventory (LLI).

6. The electrical device of claim 1 wherein:
the state of the battery is a state of charge percentage of the battery.

7. The electrical device of claim 1 wherein:
the state of the battery is a state of health percentage of the battery.

8. The electrical device of claim 1 wherein:
the controller is configured to execute the program stored in the controller to apply continuity conditions and boundary conditions to solve the first polynomial function and the second polynomial function.

9. The electrical device of claim 1 wherein:
the controller is configured to execute the program stored in the controller to solve the first polynomial function and the second polynomial function using a shape function.

10. (canceled)

11. The electrical device of claim 1 wherein:
step (i) comprises calculating the terminal voltage of the battery using the electrochemical model that receives as inputs the temperature reading from the temperature sensor and the current flowing from the battery and outputs the terminal voltage of the battery when the battery is charged or discharged at a current below a C rate, and calculating the terminal voltage of the battery using an additional electrochemical model that receives as inputs the temperature reading from the temperature sensor and the current flowing from the battery and outputs the terminal voltage of the battery when the battery is charged or discharged at a current above the C rate, wherein the additional electrochemical model calculates the terminal voltage of the battery using a lithium-ion concentration distribution as a first polynomial function and an electrolyte potential distribution as a second polynomial function.

12. (canceled)

13. (canceled)

14. (canceled)

15. The electrical device of claim 1 wherein:
the electrochemical model calculates the terminal voltage of the battery using interfacial current density of the battery.

16. (canceled)

17. (canceled)

18. (canceled)

19. (canceled)

20. (canceled)

21. A method for estimating a terminal voltage of a battery including one or more electrochemical cells, the method comprising:
(a) calculating a terminal voltage of the battery using an electrochemical model that receives as inputs a temperature reading from a temperature sensor positioned in at least one of the electrochemical cells and current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function.

22. The method of claim 21 wherein:
the electrochemical model is a single-particle model.

23. The method of claim 21 wherein:
the electrochemical model is a pseudo-two-dimensional electrochemical model.

24. The method of claim 21 wherein:
the electrochemical model can couple with a degradation mechanism.

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. A method for estimating a state of a battery including one or more electrochemical cells, the method comprising:
(a) calculating a terminal voltage of the battery using an electrochemical model that receives as inputs a temperature reading from a temperature sensor positioned in at least one of the electrochemical cells and current flowing from the battery and outputs the terminal voltage of the battery, wherein the electrochemical model calculates the terminal voltage of the battery using a lithium-ion concentration distribution as a first polynomial function and an electrolyte potential distribution as a second polynomial function; and
(b) determining a state of the battery based on the terminal voltage.

40. The method of claim 39 wherein:
the electrochemical model is a single-particle model.

41. The method of claim 39 wherein:
the electrochemical model is a pseudo-two-dimensional electrochemical model.

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. A method in a data processing system comprising at least one processor and at least one memory, the at least one memory comprising instructions executed by the at least one processor to implement a terminal voltage estimation system for a battery including one or more electrochemical cells, the method comprising:
(a) receiving as inputs a temperature from at least one of the electrochemical cells and a current flowing from the battery; and
(b) calculating a terminal voltage of the battery using an electrochemical model that receives as inputs the temperature reading and the current and outputs the terminal voltage of the battery, wherein the electrochemical model calculates the terminal voltage of the battery using a lithium-ion concentration distribution as a first polynomial function and an electrolyte potential distribution as a second polynomial function.

60. (canceled)

61. (canceled)

62. (canceled)

63. (canceled)

64. (canceled)

65. (canceled)

66. (canceled)

67. (canceled)

68. (canceled)

69. (canceled)

70. (canceled)

71. (canceled)

72. (canceled)

73. (canceled)

74. (canceled)

75. (canceled)

76. A method in a data processing system comprising at least one processor and at least one memory, the at least one memory comprising instructions executed by the at least one processor to implement a state estimation system for a battery including one or more electrochemical cells, the method comprising:
(a) receiving as inputs a temperature from at least one of the electrochemical cells and a current flowing from the battery;
(b) calculating a terminal voltage of the battery using an electrochemical model that receives as inputs the temperature reading and the current and outputs the terminal voltage of the battery, wherein the electrochemical model calculates the terminal voltage of the battery using a lithium-ion concentration distribution as a first polynomial function and an electrolyte potential distribution as a second polynomial function; and
(c) determining a state of the battery based on the terminal voltage.

77. (canceled)

78. (canceled)

79. (canceled)

80. (canceled)

81. (canceled)

82. (canceled)

83. (canceled)

84. (canceled)

85. (canceled)

86. (canceled)

87. (canceled)

88. (canceled)

89. (canceled)

90. (canceled)

91. (canceled)

92. (canceled)

93. (canceled)

94. (canceled)
